(19) United States
(12) Patent Application Publication
(10) Pub. No.: US 2025/0305131 A1
(43) Pub. Date: Oct. 2, 2025

(54) LOW TEMPERATURE THERMAL DEPOSITION OF SILICON-CONTAINING FILMS USING LOW WATER CONTENT HYDROGEN PEROXIDE

(71) Applicant: Gelest, Inc., Morrisville, PA (US)

(72) Inventors: Chad Michael BRICK, Yardley, PA (US); Tomoyuki Ogata, Tokyo (JP)

(21) Appl. No.: 19/089,569

(22) Filed: Mar. 25, 2025

Related U.S. Application Data
(60) Provisional application No. 63/569,828, filed on Mar. 26, 2024.
(60) Provisional application No. 63/642,956, filed on May 6, 2024.

(51) Int. Cl. C23C 16/455; C23C 16/04; C23C 16/32; C23C 16/40; C23C 16/56

(52) U.S. Cl. CPC C23C 16/45527; C23C 16/042; C23C 16/32; C23C 16/402; C23C 16/45553; C23C 16/56

(57) ABSTRACT

Provided are methods for low temperature thermal deposition of silicon-containing films. The methods provide selective deposition on a variety of substrates with high deposition rates and short cycle times.

### CROSS-REFERENCE TO RELATED APPLICATIONS

This application claims priority to co-pending U.S. provisional application No. 63/569,828, filed Mar. 26, 2024, and co-pending U.S. provisional application No. 63/642,956, filed May 6, 2024, the disclosures of which are herein incorporated by reference in their entireties.

### BACKGROUND OF THE INVENTION

Silicon dioxide (SiO₂) and silicon oxycarbide (SiOC) films are vital materials in industry and are used extensively in a wide range of applications for purposes such as insulation, passivation, encapsulation, and gate dielectrics. These films may be utilized in a variety of applications, such as in semiconductor device manufacture, both as permanent dielectric films or as sacrificial structures such as hard masks, etch stops, or lithographic processes, such as double-patterning; in biomedical and dental applications such as coatings for powders comprising active pharmaceutical ingredients or vaccines, implantable devices such as stents, shunts, and meshes, tissue engineering scaffolds, lenses, pharmaceutical delivery devices such as syringes, vials or catheters, medical devices, biosensors, bioelectronic devices, or bioassay devices; or as coatings in industrial applications such as metal passivation or anticorrosion, encapsulation of sensitive devices or chemical compounds such as organic emitting diodes, catalysts, or perovskite solar cells, or the coating of membranes. Traditional thermal methods for depositing silicon-based films, such as thermal chemical vapor deposition (CVD) or atomic layer deposition (ALD), involve high processing temperatures and aggressive oxidants such as ozone, which may damage portions of the substrate. In contrast, plasma-enhanced chemical vapor deposition (PECVD) or plasma-enhanced atomic layer deposition (PEALD) can operate at significantly reduced temperatures relative to thermal CVD and ALD, even as low as room temperature. However, plasma-based processes suffer from line-of-sight issues that limit film conformality, are unsuitable for substrates with complex geometries or high aspect ratios, and often result in plasma damage to the substrate, which can limit the applications in which plasma can be used.

Furthermore, both thermal ozone and plasma-based processes remove most carbon from the film, which is undesirable in many applications. While low temperature (<150° C.) thermal deposition of silicon dioxide and silicon oxycarbide have been reported using water as oxidant, and these processes are generally protective of silicon-carbon bonds, the kinetics of these reactions is too slow to be of practical industrial value in most applications even when enhanced by amine-based catalysis. Thus, the low-temperature deposition of ALD films onto temperature-sensitive materials or devices is known, most reports only discuss ALD films such as aluminum oxide, titanium dioxide, or zinc oxide, which can be readily deposited by ALD at low temperature using weakly-oxidizing water as the oxidant. Reports of low-temperature silicon dioxide or silicon oxycarbide films either use plasma-based processes that are not suitable for many materials or device geometries, or employ impractically slow deposition processes. Given their excellent barrier properties, dielectric properties, biocompatibility, and ease of chemical functionalization, there is a strong need for a practical low-temperature thermal atomic layer deposition process for SiO₂ and SiOC films across a variety of industries.

Low-temperature (<150° C.) plasma-based atomic layer deposition of silicon-based films is widely used in industry and many detailed studies have been reported. Plasma-based atomic layer deposition of silicon dioxide films in particular is utilized in advanced multi-patterning lithographic processes, where ALD silicon dioxide films are conformally coated onto lithographically defined mandrels and then anisotropically etched to reveal two features formed by the silicon dioxide that had deposited on the mandrel sidewalls. This scheme may then be repeated to perform quadruple or octuple patterning, as is known in the art. Because of the poor thermal and plasma stability of developed photoresists, mandrels are typically formed by first exposing and developing a photoresist, and then etching that pattern into a mandrel-forming layer that is more suitable for the subsequent silicon dioxide ALD deposition and etching processes. However, issues around plasma stability of the mandrels and film conformality remain.

In addition, a low-temperature thermal process for the deposition of silicon-based films, such as silicon dioxide or carbon-containing silicon dioxide (SiOC) is also desired in the field of area-selective deposition (ASD), where films are deposited only on select regions of a patterned substrate. Plasma-based strategies for ASD are challenging because of the strong chemical reactivity of plasmas, which can quickly erode the chemical blocking agents that are used to suppress growth on non-targeted regions of the patterned substrate.

An example of a plasma-based ASD process was described in U.S. Pat. No. 11,139,163, where a three-step sequence of alkoxysilane precursor, hydrogen-containing plasma, and fluorine-based etching was used to selectively deposit SiOC films on dielectric regions of a substrate relative to metallic regions at temperatures around 200° C. Due to the relatively high temperature and aggressive plasma and etching conditions, selective passivation of non-growth areas using small organic molecules would be challenging and is not reported, limiting the selection of non-growth surfaces to whichever surfaces inherently show non-growth behavior in this process. Furthermore, the utilization of plasma can make conformality in high-aspect ratio structures challenging, limiting the types of device structures to which this invention can be applied. Another limitation of this disclosure is the potential for substrate damage via either the plasma process or etching process, further limiting which substrate regions may be exposed to the deposition process. Yet another limitation is the use of alkoxysilanes, whose oxygen atoms are the source of oxygen in the deposited SiOC film. Compared to the more commonly used aminosilanes precursors used in PEALD, the reaction rate of alkoxysilanes with SiOC, silicon dioxide, or silicon nitride substrates is low. While not reported, it may be inferred that the growth rate of the disclosed process is correspondingly low, and this issue is further compounded by the etch process which is required in order to remove unwanted nucleation and film growth on the unblocked non-target regions. This step not only adds a third process to the cycle, but also reduces the thickness of the desired SiOC film during each etch cycle and thus would be expected to lower the overall growth rate of the process.

Non-selective thermal deposition of silicon-based films with ozone as oxidant has been widely studied. However, there are many limitations with ozone, the first being that deposition rate is sensitive to temperature and generally falls below the practical limit of 0.5 nm/cycle below 100° C. Furthermore, like oxygen plasma, ozone is a powerful oxidant, making both the formation of carbon-containing SiOC films and selective deposition challenging due to ozone's indiscriminate reactivity.

In Hirose et al., (Thin Solid Films 519; 270-275 (2010)) the atomic layer deposition of silicon dioxide using tris(dimethylamino)silane as the silane source and ozone as the oxidant was discussed. The authors demonstrated that while ozone readily oxidized the dimethylamino groups of the precursor at room temperature, an exposure of the resulting film to water vapor at 155° C. to 160° C. was required to regenerate the hydroxylated surface required for subsequent deposition cycles.

In Lee et al., (Ceramics International 43; 2095-2099 (2017)), di-isopropylaminosilane was used in conjunction with ozone in an atomic layer deposition process to deposit silicon dioxide films at temperatures as low as 100° C. However, there was a significant decline in deposition rate from 150° C. to 100° C., decreasing from about 0.125 nm/cycle to about 0.050 nm cycle, indicating that further lowering of temperature while maintaining practical deposition rates of at least 0.050 nm/cycle was unlikely.

In Bachmann et al., (Angew. Chem. Int. Ed. 47, 6177-6179 (2008)), a self-catalytic method of growing silicon dioxide films was developed using (3-aminopropyl)triethoxysilane using a three-step sequence of silane precursor, water, and ozone. This process is advantageous in that the precursor contains no Si—H bonds which can remain in the final film and thereby increase the film's etch rate. However, the growth rate was marginal, falling from 0.06 nm/cycle at 150° C. to 0.035 nm/cycle at 120° C., the lowest temperature reported. The reported optimal cycle time of 73.2 seconds is also higher than desired for practical implementation. Furthermore, the self-catalytic precursors used in this work readily undergo unwanted polymerization reactions, which can contaminate or damage the deposition tool's chamber, lines, or pumps.

In Ahn et al., (J. Vac. Sci. Technol. A 35, 01B131 (2017)), atomic layer deposition using tris(dimethylamino)silane and ozone was studied over the temperature range of 400° C. to 200° C., with the deposition rate declining from about 0.6 nm/cycle at 400° C. to about 0.3 nm/cycle at 200° C.

Reports of selective processes using ozone are more limited. U.S. Patent Application Publication No. 2024/0047196 disclosed a selective thermal atomic layer deposition process for the deposition of a silicon-based dielectric on a dielectric surface relative to a metal surface that utilized a repeated three-step “ABC” sequence of blocking agent, silicon precursor, and oxidant. The relatively high temperatures and strong ozone-based oxidation conditions of the disclosed examples resulted in partial oxidation of the blocking layer, necessitating its reapplication during every cycle. Furthermore, the disclosed process required a metal oxidation step to precede the repeated “ABC” growth cycle, which may be disadvantageous in some applications. Additionally, the disclosure was limited to “dielectric on dielectric” selective deposition processes with metal non-growth surfaces due to the requirement of reestablishing the blocking layer every cycle, which is precluded if the newly growing surface is chemically similar to any of the non-growth surfaces. Yet another limitation of this disclosure was that the disclosed process was limited to either ten ALD cycles using a hydrocarbon based blocking agent or thirty cycles using a perfluorinated blocking agent. While the result film thicknesses were not reported, ten and thirty ALD cycles would be expected to result in films of less than 1 nm and 3 nm respectively based on data for similar precursors provided by Lee et al. and Ahn et al., far below industrially relevant targets of 5 nm to 10 nm or more. Furthermore, the use of perfluorinated materials is undesirable due to their environmental impact and resulting regulatory concerns. A further limitation of the disclosed examples is the incompatibility of silicon-carbon bonds with ozone-based oxidation, which are readily cleaved in such an oxidative environment. Thus the disclosure is limited to substantially carbon-free films. Carbon-containing silicon-based films are highly desirable due to their lower dielectric constant than silicon dioxide.

Studies using hydrogen peroxide/water solutions as oxidant in the formation of silicon-based films via atomic layer deposition are comparatively few. In Burton et al., (J. Phys. Chem. C, 113, 19, 8249-8257 (2009)), the atomic layer deposition of silicon dioxide using tris(dimethylamino)silane as the silane source and a solution of hydrogen peroxide in water as the oxidant was discussed over the temperature range of 150° C. to 500° C. The growth per cycle of the silicon dioxide film was reported to decrease significantly with temperature, falling to 0.046 nm/cycle by 150° C. Data at lower temperatures were not reported, and selectivity was not discussed. Due to the relatively high temperatures required for practical deposition rates, selectivity could be expected to be difficult to achieve due to the temperature instability of the chemical blocking agents typically used to suppress growth on non-target regions of the patterned substrate. Furthermore, the hydrogen peroxide/water used in this work may not be practical for industrial implementation in a vapor deposition system, due to the differing vapor pressures of water and hydrogen peroxide and the resulting changes in concentration as water is more rapidly depleted, leading to process variation. Additionally, the high reported hydrogen peroxide utilization requirements of approximately 10⁸-10⁹ Langmuirs may be a further practical limitation of this method. A Langmuir as defined herein is exposure of the substrate to 10⁻⁶ torr of pressure for one second.

Water has also been studied as the oxidant for the formation of silicon-based films by ALD. However, the reactivity of water is slow with silane precursors, and even with catalysis with compounds such as ammonia or triethylamine, cycle times are impractical for use in manufacture. For example, in Arl et al., (RSC Adv., 10, 18073 (2020)), room temperature deposition of silicon dioxide was reported using SiCl₄ as the silicon source, water as the oxidant, and ammonia catalysis. While growth per cycle of 0.18 nm/cycle was achieved, the associated cycle time of 810 seconds is unsuitable for practical implementation. Furthermore, film contamination with chlorine was evident, making the resulting films unsuitable for some applications.

In another example of a water-based ALD process for silicon-containing film formation, Yu et al. (Chem. Mater., 33, 902-909 (2021)) discussed the selective deposition of an SiOC film on an oxide substrate by blocking metallic layers with alkane thiols and using an alternating sequence of silane precursor bis(trichlorosilyl)methane and water to grow a film incorporating the bridged carbon found in the silane precursor. While good selectivity was achieved and a film of up to 10 nm could be selectively grown at a good growth per cycle of 0.148 nm/cycle, the reported cycle time of 1232 seconds is again unsuitable for practical implementation. Additionally, chlorine contamination resulting from the chlorosilane precursor is a concern for some applications.

U.S. Patent Application Publication No. 2022/0213597 discloses the use of tetraisocyanatosilane as a precursor for silicon dioxide deposition using a mixture of water and triethylamine as the oxidant system. While the growth per cycle was sufficient at 0.138 nm/cycle at 50° C. and the process is halide-free and compatible with silicon-carbon bonds, the cycle time of >240 seconds is not acceptable for practical implementation and the long precursor exposure time of 120 seconds implies high precursor usage.

Organic molecules have also been used as oxidants in SiOC film deposition. In U.S. Pat. Nos. 11,186,909 and 11,447,865 disclose a process for deposition of SiOC thin films using select silicon precursors and oxygen-containing organic oxidants such as diols and diketones. High temperatures of at least 200° C. are required. Deposition rate data is not provided on either a temporal or per-cycle basis but can be expected to be slow. Plasma-based densification of the resulting films is generally required to achieve sufficient film properties for practical utilization.

In currently known methods, the cycle times of ALD schemes using chlorosilanes and water to form SiOC films or SiO₂ films, with or without amine-based catalysis, are longer than 10 minutes, limiting their practical utility. Likewise, previous attempts to form SiOC films using isocyanatosilanes and water resulted in unacceptably long cycle times of longer than 4 minutes.

There remains a strong need in the industry for a low-temperature thermal method of forming SiO₂ and SiOC films with a deposition rate consistent with current high temperature thermal or plasma-based CVD or ALD processes. What is desired is a purely thermal process for atomic layer deposition of silicon dioxide and SiOC films at low temperatures, with acceptable deposition rates and film characteristics, and without the use of aggressive oxidants or plasmas which can damage substrates or their features, strip or damage blocking or passivation layers, or remove most or substantially all of the carbon from SiOC films.

### SUMMARY OF THE INVENTION

Aspects of the disclosure relate to a method for depositing a silicon- and oxygen-containing layer on a substrate, the method comprising:
(a) introducing a substrate into a reaction zone of a deposition chamber;
(b) heating or cooling the reaction zone to about 0° C. to about 150° C.; and
(c) performing a thermal atomic layer deposition process on the substrate to form a silicon- and oxygen-containing layer on the substrate by alternately exposing the substrate to at least one silicon-containing compound and low-water content hydrogen peroxide until a desired layer thickness is obtained.

Further aspects of the disclosure relate to a method for depositing a silicon- and carbon-containing layer on a substrate, the method comprising:
(f) introducing a substrate into a reaction zone of a deposition chamber;
(g) heating or cooling the reaction zone to about 0° C. to about 150° C.; and
(h) performing a thermal atomic layer deposition process on the substrate to form a silicon- and carbon-containing layer on the substrate by alternately exposing the substrate to two or more silicon-containing compounds and low-water content hydrogen peroxide; wherein at least one of the two or more silicon-containing compounds has Formula 1, Formula 2, Formula 3, Formula 4, or Formula 5, and at least one of the two or more silicon-containing compounds has Formula 6, Formula 7, Formula 8, Formula 9, or Formula 10; wherein at least two of the two or more silicon-containing compounds are:
delivered to the substrate simultaneously; or
delivered to the substrate sequentially, optionally separated by purges of the reaction zone, optionally separated by exposures to low-water content hydrogen peroxide, and
(i) repeating step (h) until a desired layer thickness is obtained:

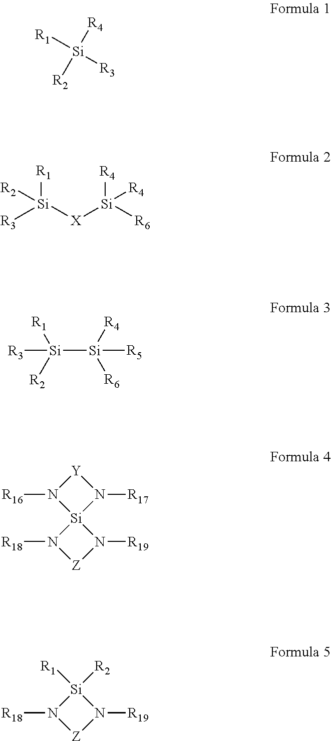

wherein R₁, R₂, R₃, R₄, R₅, R₆, R₂₆, R₂₇, R₂₉, and R₃₀ are independently selected from hydrogen, halogen, OR₇ or N(R₈)(R₉); X is O or N(R₁₀); Y and Z are —C(R₂₀)(R₂₁), —C(R₂₀)(R₂₁)—C(R₂₂)(R₂₃)—, —C(R₂₀)(R₂₁)—C(R₂₂)(R₂₃)—C(R₂₄)(R₂₅)— or —Si(R₂₆)(R₂₇)—N(R₂₈)—Si(R₂₉)R(₃₀)—, Y and Z are optionally bidentate and form a ring with the adjacent nitrogen atoms; R₇ is a linear or branched (C₁-C₈) alkyl group, or —Si(R₁₁)(R₁₂)(R₁₃), R₁₁, R₁₂ and R₁₃ are independently selected from hydrogen, halide, linear or branched (C₁-C₈)alkoxy, or —N(R₁₄)(R₁₅), R₁₄ and R₁₅ are independently hydrogen or linear or branched (C₁-C₈)alkyl; R₈, R₉, R₁₀, R₁₆, R₁₇, R₁₈, R₁₉ and R₂₈ are independently hydrogen, linear or branched (C₁-C₈) alkyl groups or Si(R₃₁)(R₃₂)(R₃₃), R₃₁, R₃₂ and R₃₃ are hydrogen, (C₁-C₈)alkyl, or N(R₃₄)(R₃₅), R₃₄ and R₃₅ are hydrogen or (C₁-C₈)alkyl; R₂₀, R₂₁, R₂₂, R₂₃, R₂₄, and R₂₅ are hydrogen, vinyl, allyl, or linear or branched (C₁-C₄) alkyl; and wherein at least half of the bonds to silicon atoms comprise Si—N bonds or silicon halide bonds;

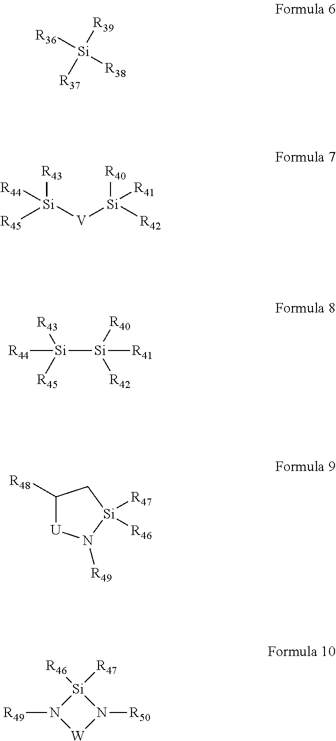

wherein R₃₆, R₃₇, R₃₈, R₃₉, R₄₀, R₄₁, R₄₂, R₄₃, R₄₄, R₄₅, R₄₆, R₄₇, R₇₉, and R₈₀ are independently selected from hydrogen, halogen, linear or branched (C₁-C₁₈) alkyl, linear or branched (C₁-C₁₈) alkoxy, vinyl, allyl, butenyl, phenyl, tolyl, cyclohexyl, cyclooctyl, or norbornyl, or N(R₅₁)(R₅₂); V is optionally bidentate and is 0, N(R₅₃), C(R₇₃)(R₇₄), linear or branched (C₁-C₈) alkyl, or —C(R₇₃)(R₇₄)—C(R₇₅)(R₇₆)— wherein C₇₃, C₇₄, C₇₅ and C₇₆ are hydrogen or linear or branched (C₁-C₈)alkyl; R₄₉, R₅₀, R₅₁, R₅₂ and R₅₃ are hydrogen, a linear or branched (C₁-C₈) alkyl group, or —Si(R₅₄)(R₅₅)(R₅₆); R₅₄, R₅₅ and R₅₆ are independently selected from hydrogen, linear or branched (C₁-C₈alkyl), linear or branched (C₁-C₈)alkoxy, or —N(R₅₇)(R₅₈); R₅₇ and R₅₈ are independently hydrogen or (C₁-C₈)alkyl; R₄₈ is hydrogen or linear or branched (C₁-C₈) hydrocarbon; W is optionally bidentate and forms a ring with the adjacent nitrogen, silicon, and/or carbon atoms and is a linear or branched (C₁-C₈) alkyl, C(R₅₉)(R₆₀), —C(R₅₉)(R₆₀)—C(R₆₁)(R₆₂)—, —C(R₅₉)(R₆₀)—C(R₆₁)(R₆₂)—C(R₆₃)(R₆₄)— or —Si(R₆₅)(R₆₆)—N(R₆₇)—Si(R₆₈)(R₆₉)—; R₅₉, R₆₀, R₆₁, R₆₂, R₆₃, R₆₄ are independently hydrogen, linear or branched (C₁-C₈)alkyl; R₆₅, R₆₆, R₆₈ and R₆₉ are hydrogen, halide, (C₁-C₈) alkyl, O(R₇₀) or N(R₇₁)(R₇₂); R₇₀ is linear or branched (C₁-C₈)alkyl; U is C(R₇₇)(R₇₈) or Si(R₇₉)Si(R₈₀); R₆₇, R₇₁, R₇₂, R₇₇, and R₇₈ are independently hydrogen or linear or branched (C₁-C₈)alkyl; and wherein the precursor compound contains at least one silicon-nitrogen or silicon-halide bond, and at least one silicon-carbon bond.

Additional aspects of the disclosure relate to method for selectively depositing a silicon-containing layer on a patterned substrate, the method comprising:
(j) introducing a patterned substrate into a reaction zone of a deposition chamber;
(k) heating or cooling the reaction zone to about 0° C. to about 150° C.;
(l) performing a thermal atomic layer deposition process on the substrate to form a silicon-containing layer on the substrate by alternately exposing the substrate to low-water content hydrogen peroxide and at least one silicon-containing compound having Formula 1, Formula 2, Formula 3, Formula 4, or Formula 5 until a desired layer thickness is obtained; or
(m) performing a thermal atomic layer deposition process on the substrate to form a silicon- and carbon-containing layer on the substrate by alternately exposing the substrate to two or more silicon-containing compounds and low-water content hydrogen peroxide; wherein at least one of the two or more silicon-containing compounds has Formula 1, Formula 2, Formula 3, Formula 4, or Formula 5, and at least one of the two or more silicon-containing compounds has Formula 6, Formula 7, Formula 8, Formula 9, or Formula 10; wherein at least two of the two or more silicon-containing compounds are:
delivered to the substrate simultaneously; or
delivered to the substrate sequentially, optionally separated by purges of the reaction zone, optionally separated by exposures to low-water content hydrogen peroxide; and
(n) repeating step (m) until a desired layer thickness is reached;
wherein the method further comprises:
prior to step (j): (j2) performing one or more substrate passivation steps; and/or
prior to step (k): (k2) performing one or more substrate passivation steps;

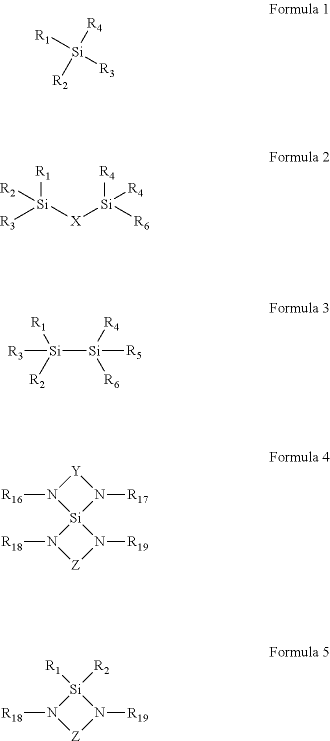

wherein R₁, R₂, R₃, R₄, R₅, R₆, R₂₆, R₂₇, R₂₉, and R₃₀ are independently selected from hydrogen, halogen, OR₇ or N(R₈)(R₉); X is O or N(R₁₀); Y and Z are —C(R₂₀)(R₂₁), —C(R₂₀)(R₂₁)—C(R₂₂)(R₂₃)—, —C(R₂₀)(R₂₁)—C(R₂₂)(R₂₃)—C(R₂₄)(R₂₅)— or —Si(R₂₆)(R₂₇)—N(R₂₈)—Si(R₂₉)R(₃₀)—, Y and Z are optionally bidentate and form a ring with the adjacent nitrogen atoms; R₇ is a linear or branched (C₁-C₈) alkyl group, or —Si(R₁₁)(R₁₂)(R₁₃), R₁₁, R₁₂ and R₁₃ are independently selected from hydrogen, halide, linear or branched (C₁-C₈)alkoxy, or —N(R₁₄)(R₁₅), R₁₄ and R₁₅ are independently hydrogen or linear or branched (C₁-C₈)alkyl; R₈, R₉, R₁₀, R₁₆, R₁₇, R₁₈, R₁₉ and R₂₈ are independently hydrogen, linear or branched (C₁-C₈) alkyl groups or Si(R₃₁)(R₃₂)(R₃₃), R₃₁, R₃₂ and R₃₃ are hydrogen, (C₁-C₈)alkyl, or N(R₃₄)(R₃₅), R₃₄ and R₃₅ are hydrogen or (C₁-C₈)alkyl; R₂₀, R₂₁, R₂₂, R₂₃, R₂₄, and R₂₅ are hydrogen, vinyl, allyl, or linear or branched (C₁-C₄) alkyl; and wherein at least half of the bonds to silicon atoms comprise Si—N bonds or silicon halide bonds;

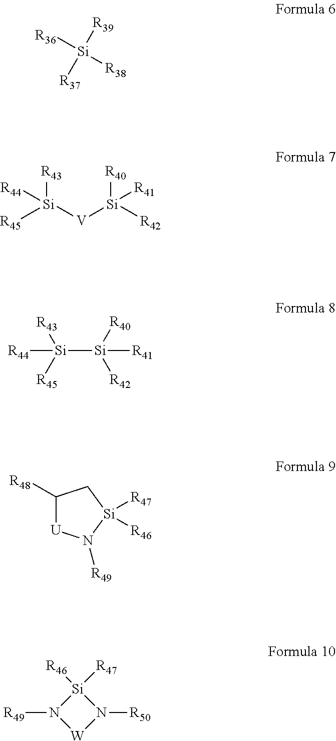

wherein R₃₆, R₃₇, R₃₈, R₃₉, R₄₀, R₄₁, R₄₂, R₄₃, R₄₄, R₄₅, R₄₆, R₄₇, R₇₉, and R₈₀ are independently selected from hydrogen, halogen, linear or branched (C₁-C₁₈) alkyl, linear or branched (C₁-C₁₈) alkoxy, vinyl, allyl, butenyl, phenyl, tolyl, cyclohexyl, cyclooctyl, or norbornyl, or N(R₅₁)(R₅₂); V is optionally bidentate and is O, N(R₅₃), C(R₇₃)(R₇₄), linear or branched (C₁-C₈) alkyl, or —C(R₇₃)(R₇₄)—C(R₇₅)(R₇₆)— wherein C₇₃, C₇₄, C₇₅ and C₇₆ are hydrogen or linear or branched (C₁-C₈)alkyl; R₄₉, R₅₀, R₅₁, R₅₂ and R₅₃ are hydrogen, a linear or branched (C₁-C₈) alkyl group, or —Si(R₅₄)(R₅₅)(R₅₆); R₅₄, R₅₅ and R₅₆ are independently selected from hydrogen, linear or branched (C₁-C₈ alkyl), linear or branched (C₁-C₈)alkoxy, or —N(R₅₇)(R₅₈); R₅₇ and R₅₈ are independently hydrogen or (C₁-C₈)alkyl; R₄₈ is hydrogen or linear or branched (C₁-C₈) hydrocarbon; W is optionally bidentate and forms a ring with the adjacent nitrogen, silicon, and/or carbon atoms and is a linear or branched (C₁-C₈) alkyl, C(R₅₉)(R₆₀), —C(R₅₉)(R₆₀)—C(R₆₁)(R₆₂)—, —C(R₅₉)(R₆₀)—C(R₆₁)(R₆₂)—C(R₆₃)(R₆₄)— or —Si(R₆₅)(R₆₆)—N(R₆₇)—Si(R₆₈)(R₆₉)—; R₅₉, R₆₀, R₆₁, R₆₂, R₆₃, R₆₄ are independently hydrogen, linear or branched (C₁-C₈)alkyl; R₆₅, R₆₆, R₆₈ and R₆₉ are hydrogen, halide, (C₁-C₈) alkyl, O(R₇₀) or N(R₇₁)(R₇₂); R₇₀ is linear or branched (C₁-C₈)alkyl; U is C(R₇₇)(R₇₈) or Si(R₇₉)Si(R₈₀); R₆₇, R₇₁, R₇₂, R₇₇, and R₇₈ are independently hydrogen or linear or branched (C₁-C₈)alkyl; and wherein the precursor compound contains at least one silicon-nitrogen or silicon-halide bond, and at least one silicon-carbon bond.

Advantageous refinements of the invention, which can be implemented alone or in combination, are specified in the dependent claims.

In summary, the following embodiments are proposed as particularly preferred in the scope of the present invention:

Embodiment 1: A method for depositing a silicon- and oxygen-containing layer on a substrate, the method comprising:
(a) introducing a substrate into a reaction zone of a deposition chamber;
(b) heating or cooling the reaction zone to about 0° C. to about 150° C.; and
(c) performing a thermal atomic layer deposition process on the substrate to form a silicon- and oxygen-containing layer on the substrate by alternately exposing the substrate to at least one silicon-containing compound and low-water content hydrogen peroxide until a desired layer thickness is obtained.

Embodiment 2: The method according to Embodiment 1, further comprising prior to step (a):
(a1) performing at least one ex-situ annealing, cleaning, etching, polishing, oxidation, reduction, photolysis, UV/ozone exposure, chemical modification, or plasma treatment of the substrate.

Embodiment 3: The method according to Embodiment 1 or 2, further comprising after step (a) and prior to step (b):
(b1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

Embodiment 4: The method according to any of Embodiments 1 to 3, wherein the at least one silicon-containing compound has Formula 1, Formula 2, Formula 3, Formula 4, or Formula 5:

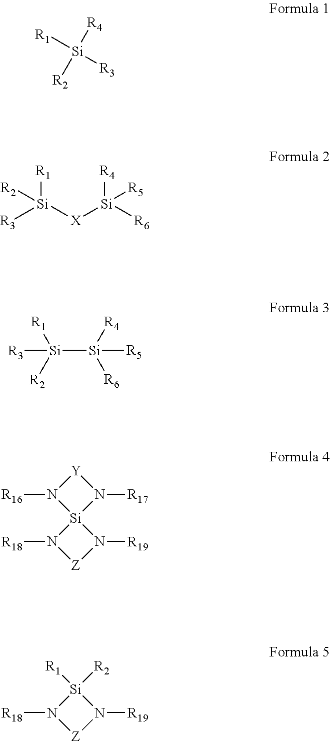

wherein R₁, R₂, R₃, R₄, R₅, R₆, R₂₆, R₂₇, R₂₉, and R₃₀ are independently selected from hydrogen, halogen, OR₇ or N(R₈)(R₉); X is O or N(R₁₀); Y and Z are —C(R₂₀)(R₂₁), —C(R₂₀)(R₂₁)—C(R₂₂)(R₂₃)—, —C(R₂₀)(R₂₁)—C(R₂₂)(R₂₃)—C(R₂₄)(R₂₅)— or —Si(R₂₆)(R₂₇)—N(R₂₈)—Si(R₂₉)R(₃₀)—, Y and Z are optionally bidentate and form a ring with the adjacent nitrogen atoms; R₇ is a linear or branched (C₁-C₈) alkyl group, or —Si(R₁₁)(R₁₂)(R₁₃), R₁₁, R₁₂ and R₁₃ are independently selected from hydrogen, halide, linear or branched (C₁-C₈)alkoxy, or —N(R₁₄)(R₁₅), R₁₄ and R₁₅ are independently hydrogen or linear or branched (C₁-C₈)alkyl; R₈, R₉, R₁₀, R₁₆, R₁₇, R₁₈, R₁₉ and R₂₈ are independently hydrogen, linear or branched (C₁-C₈) alkyl groups or Si(R₃₁)(R₃₂)(R₃₃), R₃₁, R₃₂ and R₃₃ are hydrogen, (C₁-C₈)alkyl, or N(R₃₄)(R₃₅), R₃₄ and R₃₅ are hydrogen or (C₁-C₈)alkyl; R₂₀, R₂₁, R₂₂, R₂₃, R₂₄, and R₂₅ are hydrogen, vinyl, allyl, or linear or branched (C₁-C₄) alkyl; and wherein at least half of the bonds to silicon atoms comprise Si—N bonds or silicon halide bonds.

Embodiment 5: The method according to any of Embodiments 1 to 4, wherein the at least one silicon-containing compound is tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3-diaza-2-silacyclopentane, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, penta(dimethylamino)disilane, bis(t-butylamino)silane, bis(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, hexa(dimethylamino)silazane, tetrachlorosilane, tris(dimethylamino)chlorosilane, 1,2-bis(dimethylamino)disilane, hexakis(ethylamino)disilane, tris(ethylaminosilane), tri(isopropylamino)silane, tris(n-propylamino)silane, tris(t-butyl)aminosilane, tris(n-butylaminosilane), tris(sec-butylaminosilane), tris(diethylamino)silane, tris(diisopropyl)aminosilane, tris(di-n-propyl)aminosilane, tris(di-t-butylamino)silane, tris(di-n-butylamino)silane or tris(di-sec-butylamino)silane.

Embodiment 6: The method according to Embodiment 5, wherein the at least one silicon-containing compound is tris(dimethylamino)silane, tris(dimethylamino)chlorosilane, tris(diethylamino)silane, tris(ethylamino)silane, or tris(isopropylamino)silane.

Embodiment 7: The method according to any of Embodiments 1 to 6, wherein a temperature of the reaction zone in step (b) is below about 100° C.

Embodiment 8: The method according to Embodiment 7, wherein the temperature of the reaction zone in step (b) is below about 50° C.

Embodiment 9: The method according to any of Embodiments 1 to 8, wherein the hydrogen peroxide contains less than about 30 weight percent water.

Embodiment 10: The method according to Embodiment 9, wherein the hydrogen peroxide contains less than about 20 weight percent water.

Embodiment 11: The method according to Embodiment 10, wherein the hydrogen peroxide contains less than about 10 weight percent water.

Embodiment 12: The method according to any of Embodiments 1 to 11, wherein a deposition rate of the silicon- and oxygen-containing layer is greater than about 0.3 angstroms per cycle and a cycle time is less than about 120 seconds.

Embodiment 13: The method according to Embodiment 12, where the deposition rate of the silicon- and oxygen-containing layer is greater than about 0.5 angstroms per cycle and a cycle time less than about 60 seconds.

Embodiment 14: The method according to any of Embodiments 1 to 13, wherein after step (c), the method further comprises:
(d) heating or cooling the reaction zone to about 0° C. to about 800° C.; and
(e) performing at least one in-situ passivation, annealing, cleaning, etching, polishing, oxidation, reduction, photolysis, UV/ozone exposure, or plasma treatment of the substrate.

Embodiment 15: The method according to Embodiment 14, further comprising after step (e);
(o) Repeating steps (a) or (a1) through (e) until a desired layer thickness is reached.

Embodiment 16: The method according to any of Embodiments 1 to 15, wherein the substrate comprises a semiconductor device, an active pharmaceutical ingredient, a drug product, a polymer, or a polymer film.

Embodiment 17: A method for depositing a silicon- and -carbon-containing layer on a substrate, the method comprising:
(f) introducing a substrate into a reaction zone of a deposition chamber;
(g) heating or cooling the reaction zone to about 0° C. to about 150° C.; and
(h) performing a thermal atomic layer deposition process on the substrate to form a silicon- and carbon-containing layer on the substrate by alternately exposing the substrate to two or more silicon-containing compounds and low-water content hydrogen peroxide; where at least one of the two or more silicon-containing compounds has Formula 1, Formula 2, Formula 3, Formula 4, or Formula 5, and at least one of the two or more silicon-containing compounds has Formula 6, Formula 7, Formula 8, Formula 9, or Formula 10; wherein at least two of the two or more silicon-containing compounds are:
delivered to the substrate simultaneously; or
delivered to the substrate sequentially, optionally separated by purges of the reaction zone, optionally separated by exposures to low-water content hydrogen peroxide, and
(i) repeating step (h) until a desired layer thickness is obtained:

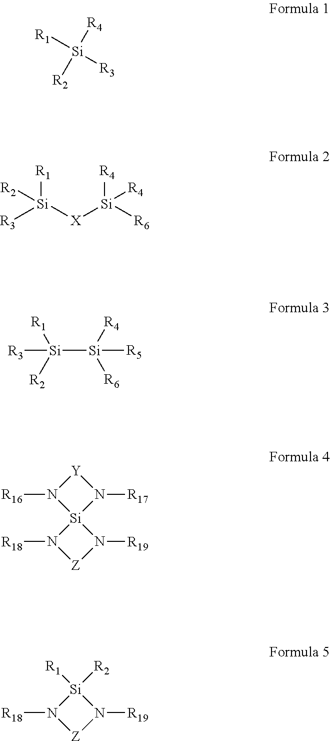

wherein R₁, R₂, R₃, R₄, R₅, R₆, R₂₆, R₂₇, R₂₉, and R₃₀ are independently selected from hydrogen, halogen, OR₇ or N(R₈)(R₉); X is O or N(R₁₀); Y and Z are —C(R₂₀)(R₂₁), —C(R₂₀)(R₂₁)—C(R₂₂)(R₂₃)—, —C(R₂₀)(R₂₁)—C(R₂₂)(R₂₃)—C(R₂₄)(R₂₅)— or —Si(R₂₆)(R₂₇)—N(R₂₈)—Si(R₂₉)R(₃₀)—, Y and Z are optionally bidentate and form a ring with the adjacent nitrogen atoms; R₇ is a linear or branched (C₁-C₈) alkyl group, or —Si(R₁₁)(R₁₂)(R₁₃), R₁₁, R₁₂ and R₁₃ are independently selected from hydrogen, halide, linear or branched (C₁-C₈)alkoxy, or —N(R₁₄)(R₁₅), R₁₄ and R₁₅ are independently hydrogen or linear or branched (C₁-C₈)alkyl; R₈, R₉, R₁₀, R₁₆, R₁₇, R₁₈, R₁₉ and R₂₈ are independently hydrogen, linear or branched (C₁-C₈) alkyl groups or Si(R₃₁)(R₃₂)(R₃₃), R₃₁, R₃₂ and R₃₃ are hydrogen, (C₁-C₈)alkyl, or N(R₃₄)(R₃₅), R₃₄ and R₃₅ are hydrogen or (C₁-C₈)alkyl; R₂₀, R₂₁, R₂₂, R₂₃, R₂₄, and R₂₅ are hydrogen, vinyl, allyl, or linear or branched (C₁-C₄) alkyl; and wherein at least half of the bonds to silicon atoms comprise Si—N bonds or silicon halide bonds;

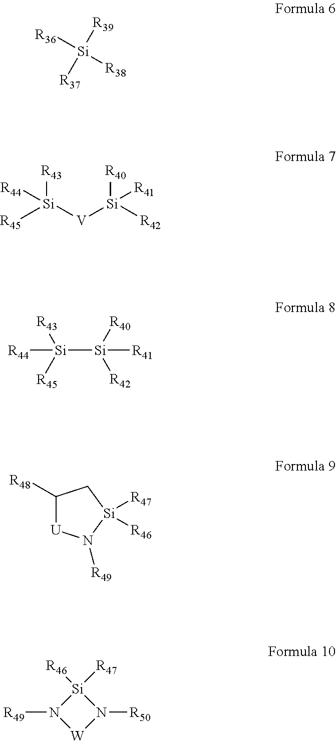

wherein R₃₆, R₃₇, R₃₈, R₃₉, R₄₀, R₄₁, R₄₂, R₄₃, R₄₄, R₄₅, R₄₆, R₄₇, R₇₉, and R₈₀ are independently selected from hydrogen, halogen, linear or branched (C₁-C₁₈) alkyl, linear or branched (C₁-C₁₈) alkoxy, vinyl, allyl, butenyl, phenyl, tolyl, cyclohexyl, cyclooctyl, or norbornyl, or N(R₅₁)(R₅₂); V is optionally bidentate and is O, N(R₅₃), C(R₇₃)(R₇₄), linear or branched (C₁-C₈) alkyl, or —C(R₇₃)(R₇₄)—C(R₇₅)(R₇₆)— where C₇₃, C₇₄, C₇₅ and C₇₆ are hydrogen or linear or branched (C₁-C₈)alkyl; R₄₉, R₅₀, R₅₁, R₅₂ and R₅₃ are hydrogen, a linear or branched (C₁-C₈) alkyl group, or —Si(R₅₄)(R₅₅)(R₅₆); R₅₄, R₅₅ and R₅₆ are independently selected from hydrogen, linear or branched (C₁-C₈alkyl), linear or branched (C₁-C₈)alkoxy, or —N(R₅₇)(R₅₈); R₅₇ and R₅₈ are independently hydrogen or (C₁-C₈)alkyl; R₄₈ is hydrogen or linear or branched (C₁-C₈) hydrocarbon; W is optionally bidentate and forms a ring with the adjacent nitrogen, silicon, and/or carbon atoms and is a linear or branched (C₁-C₈) alkyl, C(R₅₉)(R₆₀), —C(R₅₉)(R₆₀)—C(R₆₁)(R₆₂)—, —C(R₅₉)(R₆₀)—C(R₆₁)(R₆₂)—C(R₆₃)(R₆₄)— or —Si(R₆₅)(R₆₆)—N(R₆₇)—Si(R₆₈)(R₆₉)—; R₅₉, R₆₀, R₆₁, R₆₂, R₆₃, R₆₄ are independently hydrogen, linear or branched (C₁-C₈)alkyl; R₆₅, R₆₆, R₆₈ and R₆₉ are hydrogen, halide, (C₁-C₈) alkyl, O(R₇₀) or N(R₇₁)(R₇₂); R₇₀ is linear or branched (C₁-C₈)alkyl; U is C(R₇₇)(R₇₈) or Si(R₇₉)Si(R₈₀); R₆₇, R₇₁, R₇₂, R₇₇, and R₇₈ are independently hydrogen or linear or branched (C₁-C₈)alkyl; and wherein the precursor compound contains at least one silicon-nitrogen or silicon-halide bond, and at least one silicon-carbon bond.

Embodiment 18: The method according to Embodiment 17, wherein all but a final exposure of the substrate to the two or more silicon-containing compounds covers only a fraction of the available substrate surface or is followed by an exposure to low-water content hydrogen peroxide.

Embodiment 19: The method according to Embodiment 17 or 18, further comprising prior to step (f):
(f1) performing at least one ex-situ annealing, cleaning, etching, polishing, oxidation, reduction, photolysis, UV/ozone exposure, chemical modification, or plasma treatment of the substrate.

Embodiment 20: The method according to any of Embodiments 17 to 19, further comprising after step (f) and prior to step (g):
(g1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

Embodiment 21: The method according to any of Embodiments 17 to 20, wherein at least one of the silicon-containing compounds having Formula 1, Formula 2, Formula 3, Formula 4, or Formula 5 is tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3-diaza-2-silacyclopentane, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, penta(dimethylamino)disilane, bis(t-butylamino)silane, bis(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, hexa(dimethylamino)silazane, tetrachlorosilane, tris(dimethylamino)chlorosilane, 1,2-bis(dimethylamino)disilane, hexakis(ethylamino)disilane, tris(ethylaminosilane), tri(isopropylamino)silane, tris(n-propylamino)silane, tris(t-butyl)aminosilanes, tris(n-butylaminosilane), tris(sec-butylaminosilane), tris(diethylamino)silane, tris(diisopropyl)aminosilane, tris(di-n-propyl)aminosilane, tris(di-t-butylamino)silane, tris(di-n-butylamino)silane or tris(di-sec-butylamino)silane.

Embodiment 22: The method according to Embodiment 21, wherein at least one of the silicon-containing compounds having Formula 1, Formula 2, Formula 3, Formula 4, or Formula 5 is tris(dimethylamino)silane, tris(dimethylamino)chlorosilane, tris(diethylamino)silane, tris(ethylamino)silane, or tris(isopropylamino)silane.

Embodiment 23: The method according to any of Embodiments 17 to 22, wherein at least one of the silicon-containing compounds having Formula 6, Formula 7, Formula 8, Formula 9, or Formula 10 is tris(dimethylamino)methylsilane, bis(diethylamino)methylsilane, di(isopropylamino)methylsilane, dimethylamino-(dimethoxy)methylsilane, tris(dimethylamino)(t-butyl)silane, tris(dimethylamino)phenylsilane, dimethylamino(dimethyl)cyclohexylsilane, 2-(dimethylaminosilyl)bicyclo[2.2.1]heptane, tris(dimethylamino)decylsilane, n-methyl-aza-2,2,4-trimethylsilacyclopentane, n-trimethylsilyl-aza-4-methylsilacyclopentane, n-(n-butyl)-aza-silacyclopentane, n-ethyl-aza-4-methyl-2,2-dimethoxysilacyclopentane, 1,2,2,3-tetramethyl-1,3-diaza-2-silacyclopentane, N-methyl-aza-4-methyl-2-methoxy-2-(n-butyl)silacyclopentane, bis(dimethylaminomethylsilyl)methane, bis(tris(dimethylamino)silyl)methane, bis(bis(dimethylamino)methylsilyl)methane, 1,1-bis(tris(dimethylamino)silyl)ethane, bis(bis(dimethylamino)methylsilylamino)-(dimethylamino)methylsilane, (bis(dimethylamino)methylsilylamino)-bis(dimethylamino)methylsilane, bis(bis(dimethylamino)silyl)methane, (bis(ethylamino)methylsilyl)bis(ethylamino)-methylsilane, and 1,3,5-tris(1-methylethyl)-1,3,5-triaza-2,4,6-trimethyl-2,4,6-trisilacyclohexane, 2,2,5,5-tetramethyl-1-aza-2,5-disilacyclopentane, dimethylamino(trimethoxy)silane, or n-trimethylsilyl-aza-silacyclopentane

Embodiment 24: The method according to Embodiment 23, wherein at least one of the silicon-containing compounds having Formula 6, Formula 7, Formula 8, Formula 9, or Formula 10 is tris(dimethylamino)methylsilane, bis(tris(dimethylamino)silyl)methane, n-methyl-aza-2,2,4-trimethylsilacyclopentane or bis(dimethylaminomethylsilyl)methane.

Embodiment 25: The method according to any of Embodiments 17 to 24, wherein a temperature of the reaction zone in step (g) is below about 100° C.

Embodiment 26: The method according to Embodiment 25, wherein the temperature of the reaction zone in step (g) is below about 50° C.

Embodiment 27: The method according to any of Embodiments 17 to 26, wherein the hydrogen peroxide contains less than about 30 weight percent water.

Embodiment 28: The method according to Embodiment 27, wherein the hydrogen peroxide contains less than about 20 weight percent water.

Embodiment 29: The method according to Embodiment 28, wherein the hydrogen peroxide contains less than about 10 weight percent water.

Embodiment 30: The method according to any of Embodiments 17 to 29, wherein a deposition rate of the silicon- and carbon-containing layer is greater than about 0.3 angstroms per cycle a cycle time is less than about 120 seconds.

Embodiment 31: The method according to Embodiment 30, wherein the deposition rate of the silicon- and carbon-containing layer is greater than about 0.5 angstroms per cycle and cycle time is less than about 60 seconds.

Embodiment 32: The method according to any of Embodiments 17 to 31, wherein after step (i), the method further comprises:
(d) heating or cooling the reaction zone to about 0° C. to about 800° C.; and
(e) performing at least one in-situ passivation, annealing, cleaning, etching, polishing, oxidation, reduction, photolysis, UV/ozone exposure, or plasma treatment of the substrate.

Embodiment 33: The method according to Embodiment 32, further comprising after step (e);
(o) repeating steps (f) or (f1) through (e) until a desired layer thickness is reached.

Embodiment 34: The method according to any of Embodiments 17 to 33, where the substrate comprises a semiconductor device, an active pharmaceutical ingredient, a drug product, a polymer, or a polymer film.

Embodiment 35: A method for selectively depositing a silicon-containing layer on a patterned substrate, the method comprising:
(j) introducing a patterned substrate into a reaction zone of a deposition chamber;
(k) heating or cooling the reaction zone to about 0° C. to about 150° C.;
(l) performing a thermal atomic layer deposition process on the substrate to form a silicon-containing layer on the substrate by alternately exposing the substrate to low-water content hydrogen peroxide and at least one silicon-containing compound having Formula 1, Formula 2, Formula 3, Formula 4, or Formula 5 until a desired layer thickness is obtained; or
(m) performing a thermal atomic layer deposition process on the substrate to form a silicon- and carbon-containing layer on the substrate by alternately exposing the substrate to two or more silicon-containing compounds and low-water content hydrogen peroxide; where at least one of the two or more silicon-containing compounds has Formula 1, Formula 2, Formula 3, Formula 4, or Formula 5, and at least one of the two or more silicon-containing compounds has Formula 6, Formula 7, Formula 8, Formula 9, or Formula 10; wherein at least two of the two or more silicon-containing compounds are:
delivered to the substrate simultaneously; or
delivered to the substrate sequentially, optionally separated by purges of the reaction zone, optionally separated by exposures to low-water content hydrogen peroxide, and
(n) repeating step (m) until a desired layer thickness is reached;
wherein the method further comprises:
prior to step (j): (j2) performing one or more substrate passivation steps; and/or
prior to step (k): (k2) performing one or more substrate passivation steps;

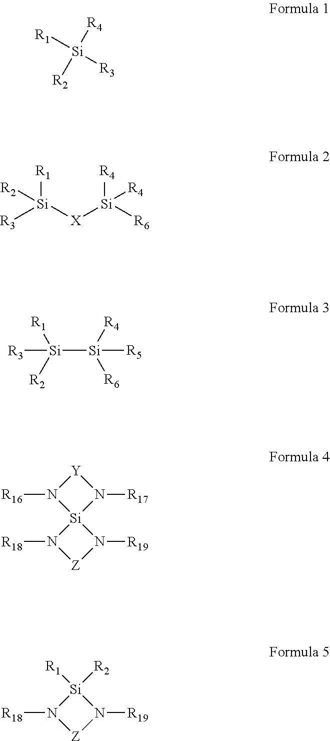

wherein R₁, R₂, R₃, R₄, R₅, R₆, R₂₆, R₂₇, R₂₉, and R₃₀ are independently selected from hydrogen, halogen, OR₇ or N(R₈)(R₉); X is O or N(R₁₀); Y and Z are —C(R₂₀)(R₂₁), —C(R₂₀)(R₂₁)—C(R₂₂)(R₂₃)—, —C(R₂₀)(R₂₁)—C(R₂₂)(R₂₃)—C(R₂₄)(R₂₅)— or —Si(R₂₆)(R₂₇)—N(R₂₈)—Si(R₂₉)R(₃₀)—, Y and Z are optionally bidentate and form a ring with the adjacent nitrogen atoms; R₇ is a linear or branched (C₁-C₈) alkyl group, or —Si(R₁₁)(R₁₂)(R₁₃), R₁₁, R₁₂ and R₁₃ are independently selected from hydrogen, halide, linear or branched (C₁-C₈)alkoxy, or —N(R₁₄)(R₁₅), R₁₄ and R₁₅ are independently hydrogen or linear or branched (C₁-C₈)alkyl; R₈, R₉, R₁₀, R₁₆, R₁₇, R₁₈, R₁₉ and R₂₈ are independently hydrogen, linear or branched (C₁-C₈) alkyl groups or Si(R₃₁)(R₃₂)(R₃₃), R₃₁, R₃₂ and R₃₃ are hydrogen, (C₁-C₈)alkyl, or N(R₃₄)(R₃₅), R₃₄ and R₃₅ are hydrogen or (C₁-C₈)alkyl; R₂₀, R₂₁, R₂₂, R₂₃, R₂₄, and R₂₅ are hydrogen, vinyl, allyl, or linear or branched (C₁-C₄) alkyl; and wherein at least half of the bonds to silicon atoms comprise Si—N bonds or silicon halide bonds;

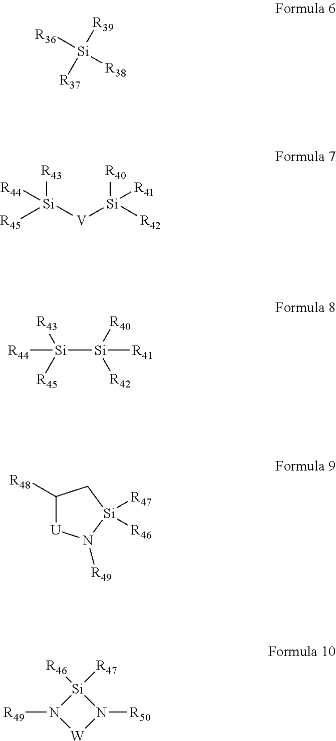

wherein R₃₆, R₃₇, R₃₈, R₃₉, R₄₀, R₄₁, R₄₂, R₄₃, R₄₄, R₄₅, R₄₆, R₄₇, R₇₉, and R₈₀ are independently selected from hydrogen, halogen, linear or branched (C₁-C₁₈) alkyl, linear or branched (C₁-C₁₈) alkoxy, vinyl, allyl, butenyl, phenyl, tolyl, cyclohexyl, cyclooctyl, or norbornyl, or N(R₅₁)(R₅₂); V is optionally bidentate and is 0, N(R₅₃), C(R₇₃)(R₇₄), linear or branched (C₁-C₈) alkyl, or —C(R₇₃)(R₇₄)—C(R₇₅)(R₇₆)— where C₇₃, C₇₄, C₇₅ and C₇₆ are hydrogen or linear or branched (C₁-C₈)alkyl; R₄₉, R₅₀, R₅₁, R₅₂ and R₅₃ are hydrogen, a linear or branched (C₁-C₈) alkyl group, or —Si(R₅₄)(R₅₅)(R₅₆); R₅₄, R₅₅ and R₅₆ are independently selected from hydrogen, linear or branched (C₁-C₈alkyl), linear or branched (C₁-C₈)alkoxy, or —N(R₅₇)(R₅₈); R₅₇ and R₅₅ are independently hydrogen or (C₁-C₈)alkyl; R₄₈ is hydrogen or linear or branched (C₁-C₈) hydrocarbon; W is optionally bidentate and forms a ring with the adjacent nitrogen, silicon, and/or carbon atoms and is a linear or branched (C₁-C₈) alkyl, C(R₅₉)(R₆₀), —C(R₅₉)(R₆₀)—C(R₆₁)(R₆₂)—, —C(R₅₉)(R₆₀)—C(R₆₁)(R₆₂)—C(R₆₃)(R₆₄)— or —Si(R₆₅)(R₆₆)—N(R₆₇)—Si(R₆₈)(R₆₉)—; R₅₉, R₆₀, R₆₁, R₆₂, R₆₃, R₆₄ are independently hydrogen, linear or branched (C₁-C₈)alkyl; R₆₅, R₆₆, R₆₈ and R₆₉ are hydrogen, halide, (C₁-C₈) alkyl, O(R₇₀) or N(R₇₁)(R₇₂); R₇₀ is linear or branched (C₁-C₈)alkyl; U is C(R₇₇)(R₇₈) or Si(R₇₉)Si(R₈₀); R₆₇, R₇₁, R₇₂, R₇₇, and R₇₈ are independently hydrogen or linear or branched (C₁-C₈)alkyl; and wherein the precursor compound contains at least one silicon-nitrogen or silicon-halide bond, and at least one silicon-carbon bond.

Embodiment 36: The method according to Embodiment 35, wherein all but a final exposure of the substrate to the two or more silicon-containing compounds covers only a fraction of the available substrate surface or is followed by an exposure to low-water content hydrogen peroxide.

Embodiment 37: The method according to Embodiment 35 or 36, further comprising prior to or after step (j2):
(j1) performing at least one ex-situ annealing, cleaning, etching, polishing, oxidation, reduction, photolysis, UV/ozone exposure, or plasma treatment of the patterned substrate.

Embodiment 38: The method according to any of Embodiments 35 to 37, further comprising prior to or after step (k2):
(k1) heating or cooling the reaction zone to about 0° C. to about 800° C. and performing at least one in-situ annealing, cleaning, etching, polishing, oxidation, reduction, photolysis, UV/ozone exposure, chemical modification, passivation or plasma treatment of the patterned substrate.

Embodiment 39: The method according to any of Embodiments 35 to 38, wherein at least one passivation step (j2) or (k2) meets the following criteria:
(i) when the substrate comprises silicon dioxide, silicon oxycarbide, silicon oxynitride, silicon carboxynitride, or germanium dioxide, exposing the patterned substrate to a compound having Formula 11 or Formula 12 to selectively passivate regions of the substrate; or
(ii) when the substrate comprises silicon nitride, titanium nitride, tantalum nitride, or germanium nitride, exposing the patterned substrate to a compound containing an aldehyde functional group to selectively passivate regions of the substrate; or
(iii) when the substrate comprises copper, cobalt, molybdenum, ruthenium, and/or tungsten, exposing the patterned substrate to an N-heterocyclic carbene or a chemical compound containing sulfur or phosphorus to selectively passivate regions of the substrate; or
(iv) when the substrate comprises silicon, germanium, copper, cobalt, molybdenum, ruthenium, or tungsten, exposing the patterned substrate to a chemical compound of Formula 13 to selectively passivate regions of the substrate; or
(v) when the substrate comprises aluminum oxide, exposing the patterned substrate to a chemical compound of Formula 11, Formula 12, Formula 14, or Formula 15 to selectively passivate regions of the substrate:

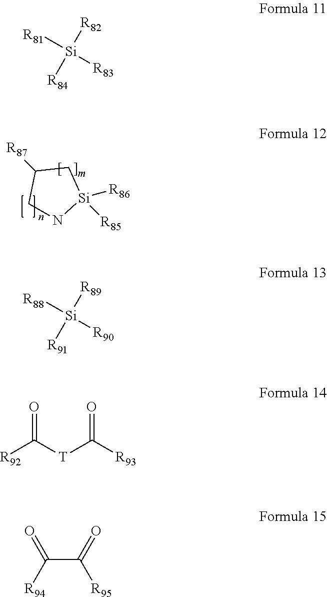

wherein R₈₁, R₈₂, R₈₃, and R₈₄ are independently hydrogen, halogen, linear or branched (C₁-C₈)alkyl, linear or branched (C₁-C₈)alkoxy, or N(R₉₆)N(₉₇), where R₉₆ and R₉₇ are independently hydrogen or (C₁-C₈)alkyl, and at least one of R₈₁, R₈₂, R₈₃, and R₈₄ is a linear or branched (C₁-C₈)alkyl and at least one is N(R₉₆)R₉₇; R₈₅ and R₈₆ are hydrogen, halogen, linear or branched (C₁-C₈)alkyl, linear or branched (C₁-C₈)alkoxy, or N(R₉₆)(R₉₇); R₈₈, R₈₉, R₉₀ and R₉₁ are independently hydrogen or (C₁-C₁₈)alkyl, and at least one of R₈₈, R₈₉, R₉₀, or R₉₁ is hydrogen and at least one is (C₁-C₁₈)alkyl; T is linear or branched (C₁-C₄)alkyl; and R₉₂, R₉₃, R₉₄ and R₉₅ are hydrogen or (C₁-C₄)alkyl; where R₈₇ is hydrogen or linear or branched (C₁-C₄)alkyl; and where n and m are 1, 2, or 3.

Embodiment 40: The method according to any of Embodiments 35 to 39, wherein the silicon-containing compound having Formula 1, Formula 2, Formula 3, Formula 4, or Formula 5 is tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3-diaza-2-silacyclopentane, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, penta(dimethylamino)disilane, bis(t-butylamino)silane, bis(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, hexa(dimethylamino)silazane, tetrachlorosilane, tris(dimethylamino)chlorosilane, 1,2-bis(dimethylamino)disilane, hexakis(ethylamino)disilane, tris(ethylaminosilane), tri(isopropylamino)silane, tris(n-propylamino)silane, tris(t-butyl)aminosilane, tris(n-butylaminosilane), tris(sec-butylaminosilane), tris(diethylamino)silane, tris(diisopropyl)aminosilane, tris(di-n-propyl)aminosilane, tris(di-t-butylamino)silane, tris(di-n-butylamino)silane or tris(di-sec-butylamino)silane.

Embodiment 41: The method according to Embodiment 40, wherein the silicon-containing compound having Formula 1, Formula 2, Formula 3, Formula 4, or Formula 5 is tris(dimethylamino)silane, tris(dimethylamino)chlorosilane, tris(diethylamino)silane, tris(ethylamino)silane, or tris(isopropylamino)silane.

Embodiment 42: The method according to any of Embodiments 35 to 41, wherein the silicon-containing compound having Formula 6, Formula 7, Formula 8, Formula 9, or Formula 10 is tris(dimethylamino)methylsilane, bis(diethylamino)methylsilane, di(isopropylamino)methylsilane, dimethylamino-(dimethoxy)methylsilane, tris(dimethylamino)(t-butyl)silane, tris(dimethylamino)phenylsilane, dimethylamino(dimethyl)cyclohexylsilane, 2-(dimethylaminosilyl)bicyclo[2.2.1]heptane, tris(dimethylamino)decylsilane, n-methyl-aza-2,2,4-trimethylsilacyclopentane, n-trimethylsilyl-aza-4-methylsilacyclopentane, n-(n-butyl)-aza-silacyclopentane, n-ethyl-aza-4-methyl-2,2-dimethoxysilacyclopentane, 1,2,2,3-tetramethyl-1,3-diaza-2-silacyclopentane, N-methyl-aza-4-methyl-2-methoxy-2-(n-butyl)silacyclopentane, bis(dimethylaminomethylsilyl)methane, bis(tris(dimethylamino)silyl)methane, bis(bis(dimethylamino)methylsilyl)methane, 1,1-bis(tris(dimethylamino)silyl)ethane, bis(bis(dimethylamino)methylsilylamino)-(dimethylamino)methylsilane, (bis(dimethylamino)methylsilylamino)-bis(dimethylamino)methylsilane, bis(bis(dimethylamino)silyl)methane, (bis(ethylamino)methylsilyl)bis(ethylamino)-methylsilane, and 1,3,5-tris(1-methylethyl)-1,3,5-triaza-2,4,6-trimethyl-2,4,6-trisilacyclohexane, 2,2,5,5-tetramethyl-1-aza-2,5-disilacyclopentane, dimethylamino(trimethoxy)silane, or n-trimethylsilyl-aza-silacyclopentane.

Embodiment 43: The method according to Embodiment 42, wherein the silicon-containing compound having Formula 6, Formula 7, Formula 8, Formula 9, or Formula 10 is tris(dimethylamino)methylsilane, bis(tris(dimethylamino)silyl)methane, n-methyl-aza-2,2,4-trimethylsilacyclopentane or bis(dimethylaminomethylsilyl)methane.

Embodiment 44: The method according to any of Embodiments 35 to 43, wherein a temperature of the reaction zone in step (k) is below about 100° C.

Embodiment 45: The method according to Embodiment 44, wherein the temperature of the reaction zone in step (k) is below about 50° C.

Embodiment 46: The method according to any of Embodiments 35 to 45, wherein the hydrogen peroxide comprises less than about 30 weight percent water.

Embodiment 47: The method according to Embodiment 46, wherein the hydrogen peroxide comprises less than about 20 weight percent water.

Embodiment 48: The method according to Embodiment 47, wherein the hydrogen peroxide comprises less than about 10 weight percent water.

Embodiment 49: The method according to any of Embodiments 35 to 48, wherein the deposition rate of the silicon- or silicon- and carbon-containing layer is greater than about 0.3 angstroms per cycle and a cycle time is less than about 120 seconds.

Embodiment 50: The method according to Embodiment 49, wherein the deposition rate of the silicon- or silicon- and carbon-containing layer is greater than about 0.5 angstroms per cycle and a cycle time less than about 60 seconds.

Embodiment 51: The method according to any of Embodiments 35 to 50, wherein the patterned substrate has growth and non-growth surfaces, and wherein a selectivity ratio between the growth and the non-growth surfaces is at least about 2:1.

Embodiment 52: The method according to Embodiment 51 wherein the selectivity ratio between the growth and the non-growth surfaces is at least about 5:1.

Embodiment 53: The method according to Embodiment 52, wherein the selectivity ratio between the growth and the non-growth surfaces is at least about 10:1.

Embodiment 54: The method according to any of Embodiments 35 to 53, wherein after step (1) or (n), the method further comprises:
(d) heating or cooling the reaction zone to about 0° C. to about 800° C.; and
(e) performing at least one in-situ passivation, annealing, cleaning, etching, polishing, oxidation, reduction, photolysis, UV/ozone exposure, or plasma treatment of the substrate.

Embodiment 55: The method according to Embodiment 54, further comprising after step (e);
(o) repeating steps (j) or (j2) through (e) until a desired layer thickness is reached.

Embodiment 56: The method according to any of Embodiments 35 to 55, wherein the substrate comprises a semiconductor device, an active pharmaceutical ingredient, a drug product, a polymer, or a polymer film.

### BRIEF DESCRIPTION OF THE SEVERAL VIEWS OF THE DRAWINGS

The foregoing summary, as well as the following detailed description of the invention, will be better understood when read in conjunction with the appended drawing. For the purpose of illustrating the invention, there is shown in the drawing embodiments which are presently preferred. It should be understood, however, that the invention is not limited to the precise arrangements and instrumentalities shown. In the drawings:

FIG. 1 is a graph showing the deposition rate of silicon dioxide films according to one embodiment of the present disclosure, along with comparative deposition rate data.

### DETAILED DESCRIPTION OF THE INVENTION

The present disclosure addresses the industry needs by providing a novel thermal method for the low-temperature deposition of silicon dioxide and silicon oxycarbide, paving the way for advancements in a broad spectrum of electronic and semiconductor technologies. Furthermore, the disclosed processes are suitable for the deposition of silicon dioxide or silicon oxide carbide on a wide variety of temperature-sensitive substrates, such as polymer films, pharmaceutical compounds, or devices with temperature-sensitive components. This technique utilizes a thermal ALD process consisting of alternating exposures of the substrate to one or more silicon-containing precursors and low-water content hydrogen peroxide. While the deposition of SiO₂ using hydrogen peroxide/water mixtures as the oxidant has previously been reported, prior work focused on the high temperature regime, with the deposition rate declining with decreasing temperature, and minimal deposition reported at 150° C., below which no further data was reported.

Surprisingly, it has now been found that with the right combination of precursor, hydrogen peroxide source, and deposition conditions, low-temperature deposition (<150° C.) of silicon dioxide can be achieved, with a deposition rate that increases with decreasing temperature. As described in more detail below, film deposition at industrially-relevant rates of up to 0.1 nm/cycle and cycle times under one minute are achievable at temperatures as low as 23° C. The low temperatures and lack of aggressive oxidants such as ozone or oxygen plasma of the processes described herein allow for the controlled introduction of carbon into the films by utilization of a second silicon precursor which comprises carbon-containing moieties, which are incorporated into the resulting silicon oxycarbide (SiOC) film in a precise manner dictated by the precursor sequence and pulse times established in the ALD process. Unlike previous attempts to form SiOC films via ALD using chlorosilanes and water, the processes according to aspects of the disclosure involve no halides, which are often retained in the film and can severely degrade performance and reliability.

In addition to forming blanket films such as SiO₂ or SiOC, there is a continuing desire in the microelectronics industry for selective deposition processes, where a film is deposited on only target “growth” regions of a patterned substrate. The gentle conditions and rapid deposition rate of the process described herein, in combination with suitable passivation schemes of the non-target “non-growth” regions of the patterned substrate, allow for a variety of selective processes discriminating between various oxides, nitrides, and metals.

The term “patterned substrate” is well understood in the art to signify a substrate in which via, pillar, channel, and trench structures have been formed through etching and/or other processes that are known in the art. It is further understood that a “patterned substrate” may consist of regions or areas of different elemental or chemical compositions, such as a substrate having discrete metallic and non-metallic regions, a substrate having discrete hydrogenated and non-hydrogenated layers on conducting and semi-conducting regions, and/or a substrate having discrete conductor and insulator regions having surfaces without hydroxyl groups and with hydroxyl groups, respectively.

Unless otherwise stated, any numerical value is to be understood as being modified in all instances by the term “about.” Thus, a numerical value typically includes ±10% of the recited value. For example, the recitation of a temperature such as “10° C.” or “about 10° C.” includes 9° C. and 11° C. and all temperatures therebetween.

All numerical ranges expressed in this disclosure expressly encompass all possible subranges, all individual numerical values within that range, including integers within such ranges and fractions and decimal amounts of the values unless the context clearly indicates otherwise. For example, a temperature range of 0° C. to about 150° C. includes temperatures of 0° C., 5° C., 10° C., 15° C., 20° C., 25° C., 30° C., 35° C., 40° C., 45° C., 50° C., 55° C., 60° C., 65° C., 70° C., 75° C., 80° C., 85° C., 90° C., 95° C., 100° C., 105° C., 110° C., 115° C., 120° C., 125° C., 130° C., 135° C., 140° C., 145° C., and 150° C. as well as all intervening temperatures and ranges. These temperatures may all be referred to as “low temperatures.”

The term “thin film” is well understood in the art and may include films ranging in thickness from a few angstroms to a few microns. More specifically, the term “thin film” may be understood to refer to a film having a thickness of less than about 1,000 nm and preferably between about 0.3 nm and about 100 nm and more preferably between about 1 nm and about 30 nm, even more preferably between about 3 nm and about 20 nm. For the purposes of this disclosure, the terms “layer”, “film,” and “thin film” are synonymous.

In certain embodiments, low-water content hydrogen peroxide is used as the oxidant for the formation of silicon dioxide or silicon oxycarbide films. Low-water content hydrogen peroxide may be delivered by a variety of means, including vapor draw, bubbling, or direct liquid injection. The low-water content hydrogen peroxide as described herein preferably contains less than about 30 weight percent water, more preferably less than about 20 weight percent water, even more preferably less than bout 10 weight percent water. While not limiting, the low-water content hydrogen peroxide source may be a hydrogen peroxide/water liquid mixture, such as a mixture containing at least about 70 weight % hydrogen peroxide in water, or a hydrogen peroxide/water mixture absorbed onto a solid. A presently preferred source of low-water content hydrogen peroxide for the applications in this disclosure is BRUTE hydrogen peroxide (RASIRC Inc, San Diego, California) which comprises high purity (>95%) hydrogen peroxide absorbed onto a proprietary solid material enclosed in a custom delivery vessel. A further an advantage of the methods described herein is the very low consumption of the low-water content hydrogen peroxide. In contrast to an exposure of 108-109 Langmuirs of hydrogen peroxide per cycle using 50% hydrogen peroxide in water as reported in Burton et al., the methods described herein require only about 10⁶-10⁷ Langmuirs of hydrogen peroxide per deposition cycle, reducing the cost of materials and abatement, as well as mitigating the potential for undesired reactions or oxidation.

According to aspects of the disclosure, the use of a low-water content hydrogen peroxide source results in the ability to achieve high deposition rates at temperatures below 150° C., as demonstrated in Comparative Example 2 and Comparative Example 3. The rate of film growth in the disclosed process is inversely related to increased temperature. The preferred temperature range for the processes described herein is about 0° C. to about 150° C., the more preferred temperature range is about 0° C. to about 75° C., and the most preferred temperature range is about 0° C. to about 50° C., including all intervening temperatures and ranges.

### First Method

A first aspect of the disclosure relates to a low-temperature thermal process for the atomic layer deposition of silicon- and oxygen-containing films is disclosed using select silicon-based precursors and low-water content hydrogen peroxide as oxidant at temperatures below 150° C. The sequence includes the following steps, described in more detail below:
(a) introducing a substrate into a reaction zone of a deposition chamber;
(b) heating or cooling the reaction zone to about 0° C. to about 150° C.; and
(c) performing a thermal atomic layer deposition process on the substrate to form a silicon- and oxygen-containing layer on the substrate by alternately exposing the substrate to at least one silicon-containing compound and low-water content hydrogen peroxide until a desired layer thickness is obtained.

In some embodiments, the method further comprises, before step (a):
(a1) performing at least one ex-situ annealing, cleaning, etching, polishing, oxidation, reduction, photolysis, UV/ozone exposure, chemical modification or plasma treatment of the substrate.

In some embodiments, the method further comprises, after step (a) and prior to step (b):
(b1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

Steps (a1) and (b1) are optional processes that may be undertaken to prepare the substrate for the atomic layer deposition process in step (c). Steps (a1) and (b1) may include one or more processes known in the art such annealing, cleaning, etching, polishing, oxidation, reduction, photolysis, UV/ozone exposure, or plasma treatment of the substrate. These processes may be independently performed before placing the substrate in the atomic layer deposition tool or reactor, termed ex-situ (step (a1)), or inside the atomic layer deposition reactor, termed in-situ (step (b1)). The temperature of any preparatory step (a1) or step (b1) may be selected independently of that of the atomic layer deposition process of step (c) and is not limited to the temperature range disclosed in step (b).

Step (c) is an atomic layer deposition process comprising exposing the substrate to at least one silicon-containing precursor, preferably, but not limited to, a precursor having Formula 1, Formula 2, Formula 3, Formula 4, and/or Formula 5 for about 0.01 s to about 60 s, preferably about 0.1 s to about 20 s, optionally purging the reactor with an inert gas such as nitrogen, helium, or argon for 0 to about 120 s, preferably 0 s to about 30 s, exposing the substrate to a gas stream containing low-water content hydrogen peroxide for about 1 s to 120 s, preferably about 5 s to about 60 s, and optionally purging the reactor with an inert gas such as nitrogen, helium, or argon for 0 s to about 120 s, preferably 0 to about 30 s.

In an alternative preferred embodiment, step (c) involves exposing the substrate to a silicon-containing precursor having Formula 1, Formula 2, Formula 3, Formula 4, or Formula 5 for about 1 to about 10 s, optionally purging the reactor with an inert gas such as nitrogen, helium, or argon for 0 s to about 20 s, exposing the substrate to a gas stream containing low-water content hydrogen peroxide for about 5 s to about 30 s, and optionally purging the reactor with an inert gas such as nitrogen, helium, or argon for 0 s to about 20 s.

Suitable silicon precursors have Formula 1, Formula 2, Formula 3, Formula 4, or Formula 5:

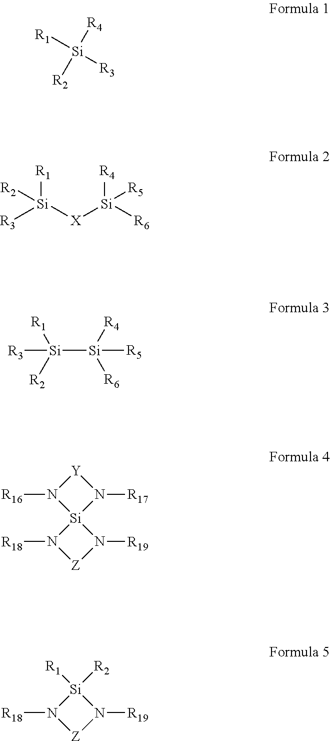

In Formulas 1-5, R₁, R₂, R₃, R₄, R₅, R₆, R₂₆, R₂₇, R₂₉, and R₃₀ are independently selected from hydrogen, halogen, OR₇ or N(R₈)(R₉); X is O or N(R₁₀); Y and Z are —C(R₂₀)(R₂₁), —C(R₂₀)(R₂₁)—C(R₂₂)(R₂₃)—, —C(R₂₀)(R₂₁)—C(R₂₂)(R₂₃)—C(R₂₄)(R₂₅)— or —Si(R₂₆)(R₂₇)—N(R₂₈)—Si(R₂₉)R(₃₀)—, Y and Z are optionally bidentate and form a ring with the adjacent nitrogen atoms; R₇ is a linear or branched (C₁-C₈) alkyl group, or —Si(R₁₁)(R₁₂)(R₁₃), R₁₁, R₁₂ and R₁₃ are independently selected from hydrogen, halide, linear or branched (C₁-C₈)alkoxy, or —N(R₁₄)(R₁₅), R₁₄ and R₁₅ are independently hydrogen or linear or branched (C₁-C₈)alkyl; R₈, R₉, R₁₀, R₁₆, R₁₇, R₁₈, R₁₉ and R₂₈ are independently hydrogen, linear or branched (C₁-C₈) alkyl groups or Si(R₃₁)(R₃₂)(R₃₃), R₃₁, R₃₂ and R₃₃ are hydrogen, (C₁-C₈)alkyl, or N(R₃₄)(R₃₅), R₃₄ and R₃₅ are hydrogen or (C₁-C₈)alkyl; R₂₀, R₂₁, R₂₂, R₂₃, R₂₄, and R₂₅ are hydrogen, vinyl, allyl, or linear or branched (C₁-C₄) alkyl; and wherein at least half of the bonds to silicon atoms comprise Si—N bonds or silicon halide bonds.

Specific examples of compounds having Formula 1, Formula 2, Formula 3, Formula 4, and Formula 5 include tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3-diaza-2-silacyclopentane, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, penta(dimethylamino)disilane, bis(t-butylamino)silane, bis(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, hexa(dimethylamino)silazane, tetrachlorosilane, tris(dimethylamino)chlorosilane, 1,2-bis(dimethylamino)disilane, hexakis(ethylamino)disilane, tris(ethylaminosilane), tri(isopropylamino)silane, tris(n-propylamino)silane, tris(t-butyl)aminosilane, tris(n-butylaminosilane), tris(sec-butylaminosilane), tris(diethylamino)silane, tris(diisopropyl)aminosilane, tris(di-n-propyl)aminosilane, tris(di-t-butylamino)silane, tris(di-n-butylamino)silane, and tris(di-sec-butylamino)silane, shown below.

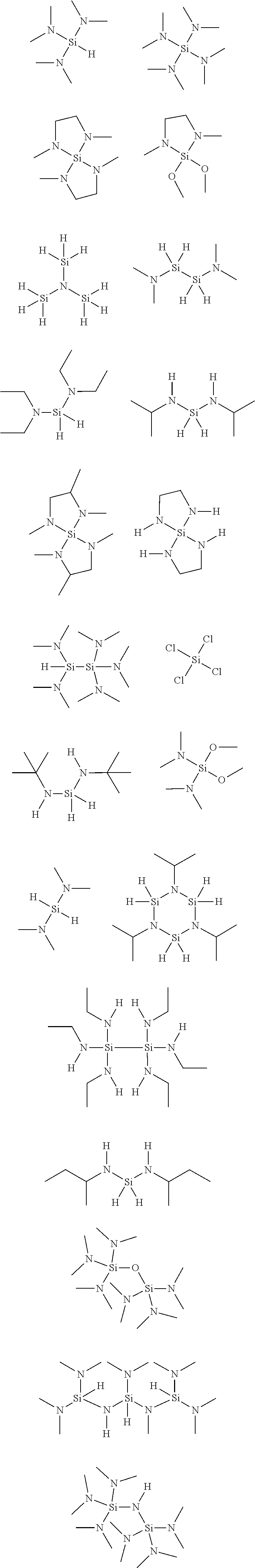

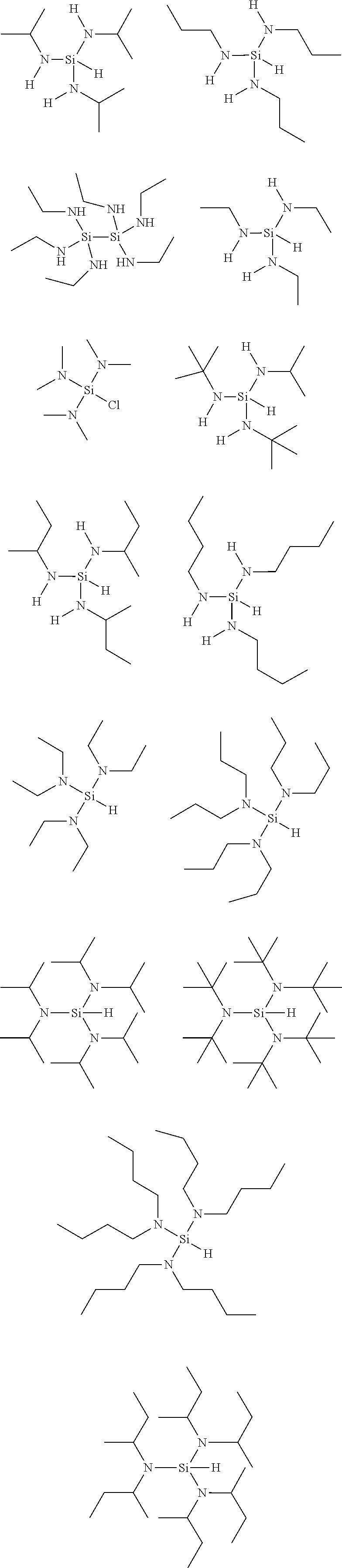

In preferred embodiments, the temperature in the reaction zone in step (b) is below about 100° C. or below about 50° C. In preferred embodiments, as described in more detail below, the deposition rate of the silicon- and oxygen-containing layer is greater than about 0.3 angstroms per cycle or greater than about 0.5 angstroms per cycle, and the cycle time is less than about 120 seconds or less than about 60 seconds.

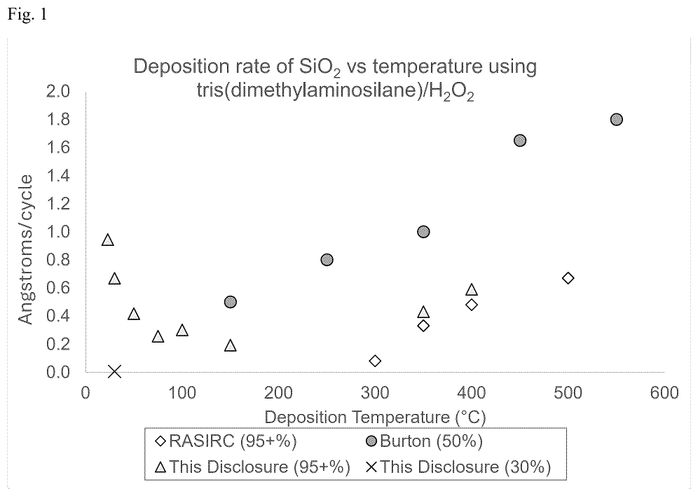

The deposition rate of silicon dioxide films utilizing the process of the first aspect of this disclosure with tris(dimethylamino)silane as the precursor is shown in FIG. 1, along with comparative deposition rate information disclosed in the literature (“AF2-MoP7 Dielectric ALD with Hydrogen Peroxide: Comparative Study of Growth and Film Characteristics for Anhydrous H₂O₂, H₂O₂/H₂O Mixtures and H₂O,” Daniel Alvarez et al., The AVS 19th International Conference on Atomic Layer Deposition (RASIRC) (2019), and Burton et al., (J. Phys. Chem. C, 113, 19, 8249-8257 (2009)). Below 75° C., an increase in deposition rate is observed when low water-content hydrogen peroxide is employed, but no increase in deposition rate it observed when high-water content hydrogen peroxide (30% hydrogen peroxide in water) is utilized under identical conditions.

### Second Method

A second aspect of the disclosure relates to a low-temperature thermal process for the atomic layer deposition of silicon and carbon-containing films using select silicon-based precursors and low-water content hydrogen peroxide as oxidant at temperatures below 150° C. The process for depositing a silicon- and carbon-containing layer on a substrate involves:
(f) introducing a substrate into a reaction zone of a deposition chamber;
(g) heating or cooling the reaction zone to about 0° C. to about 150° C.; and
(h) performing a thermal atomic layer deposition process on the substrate to form a silicon- and carbon-containing layer on the substrate by alternately exposing the substrate to two or more silicon-containing compounds and low-water content hydrogen peroxide; wherein at least one of the two or more silicon-containing compounds has Formula 1, Formula 2, Formula 3, Formula 4, or Formula 5, and at least one of the two or more silicon-containing compounds has Formula 6, Formula 7, Formula 8, Formula 9, or Formula 10; wherein at least two of the two or more silicon-containing compounds are:
delivered to the substrate simultaneously; or
delivered to the substrate sequentially, optionally separated by purges of the reaction zone, optionally separated by exposures to low-water content hydrogen peroxide; and
(i) repeating step (h) until a desired layer thickness is obtained.

In some embodiments, the method further comprises, prior to step (f):
(f1) performing at least one ex-situ annealing, cleaning, etching, polishing, oxidation, reduction, photolysis, UV/ozone exposure, chemical modification, or plasma treatment of the substrate.

In some embodiments, the method further comprises, after step (f) and prior to step (g):
(g1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

Steps (f1) and (g1) are optional processes that may be undertaken to prepare the substrate for the atomic layer deposition process in steps (h) and (i). Steps (f1) and (g1) may include one or more processes known in the art such annealing, cleaning, etching, polishing, oxidation, reduction, photolysis, UV/ozone exposure, or plasma treatment of the substrate. These processes may be independently performed before placing the substrate in the atomic layer deposition tool or reactor, termed ex-situ (step (f1)), or inside the atomic layer deposition reactor, termed in-situ (step (g1)). The temperature of any preparatory step (f1) or step (g1) may be selected independently of that of the atomic layer deposition process that is defined in steps (h) and (i) and is not limited to the temperature range disclosed in step (g).

In some embodiments of step (h), all but a final exposure of the substrate to the two or more silicon-containing compounds covers only a fraction of the available substrate surface or is followed by an exposure to low-water content hydrogen peroxide. In some embodiments of step (h), every exposure of the substrate to the two or more silicon-containing compounds covers only a fraction of the available substrate surface or is followed by an exposure to low-water content hydrogen peroxide.

Steps (h) and (i) comprise an atomic layer deposition process comprising exposing the substrate to low-water content hydrogen peroxide, at least one silicon-containing precursor having Formula 1, Formula 2, Formula 3, Formula 4, or Formula 5, and at least one precursor with silicon-carbon bonds having Formula 6, Formula 7, Formula 8, Formula 9, or Formula 10. At least two of the precursors may be exposed either simultaneously for about 0.01 s to about 60 s, more preferably about 0.1 s to about 30 s, or most preferably about 1 s to about 10 s. Alternatively, at least two of the precursors may be exposed sequentially for about 0.005 s to about 30 s, more preferably about 0.01 s to about 15 s, or most preferably about 0.1 s to about 10 s for each precursor, optionally separated by purging with an inert gas such as nitrogen, helium or argon for about 0 s to about 120 s, such that all but a final exposure of the substrate to the two or more silicon-containing compounds covers only a fraction of the available substrate surface or is followed by an additional exposure of the substrate to low-water content hydrogen peroxide for about 1 s to about 120 s, preferably about 5 s to about 60 s, most preferably about 5 s to about 30 s. The details of using a sub-saturative dose of a silicon-containing precursor in order to cover only a fraction of the available substrate and thus allow reaction of a subsequent silicon-containing precursor of the sequence are discussed below. As an alternative to using a sub-saturative dose of a silicon-containing precursor, any exposure of one of the precursors of the sequence may be followed by an exposure to low-water content hydrogen peroxide, which results in the generation of a chemically reactive surface to which the next precursor of the sequence may react. In other words, the order, conditions, and duration of the exposure of the substrate to low-water content hydrogen peroxide and to the silicon-containing precursor having Formula 1, Formula 2, Formula 3, Formula 4, and/or Formula 5 and the precursor having Formula 6, Formula 7, Formula 8, Formula 9 and/or Formula 10 are highly flexible and may be optimized by routine experimentation.

After delivering the two or more silicon precursors to the substrate surface, the atomic layer deposition sequence continues with optionally purging the reactor with an inert gas such as nitrogen, helium, or argon for about 0 s to about 120 s, preferably about 0 s to about 30 s, most preferably about 0 s to about 20 s, exposing the substrate to a gas stream containing low-water content hydrogen peroxide for about 1 s to about 120 s, preferably about 5 s to about 60 s, most preferably about 5 s to about 30 s, and optionally purging the reactor with an inert gas such as nitrogen, helium, or argon for 0 s to about 120 s, preferably about 0 s to about 30 s, most preferably 0 s to about 20 s. It is within the scope of the disclosure for a single deposition process to switch between simultaneous and sequential delivery of the silicon precursors. The deposition steps are repeated until a desired layer or film thickness is obtained.

Suitable silicon precursors for the second aspect of this disclosure have Formula 1, Formula 2, Formula 3, Formula 4, or Formula 5, as described previously, including specific examples of these compounds as described previously, and precursors containing silicon-carbon bonds have Formula 6, Formula 7, Formula 8, Formula 9, and Formula 10:

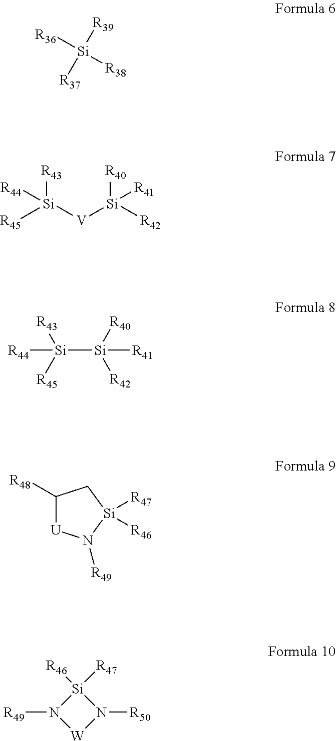

In these formulas, R₃₆, R₃₇, R₃₈, R₃₉, R₄₀, R₄₁, R₄₂, R₄₃, R₄₄, R₄₅, R₄₆, R₄₇, R₇₉, and R₈₀ are independently selected from hydrogen, halogen, linear or branched (C₁-C₁₈) alkyl, linear or branched (C₁-C₁₈) alkoxy, vinyl, allyl, butenyl, phenyl, tolyl, cyclohexyl, cyclooctyl, or norbornyl, or N(R₅₁)(R₅₂); V is optionally bidentate and is 0, N(R₅₃), C(R₇₃)(R₇₄), linear or branched (C₁-C₈) alkyl, or —C(R₇₃)(R₇₄)—C(R₇₅)(R₇₆)— wherein C₇₃, C₇₄, C₇₅ and C₇₆ are hydrogen or linear or branched (C₁-C₈)alkyl; R₄₉, R₅₀, R₅₁, R₅₂ and R₅₃ are hydrogen, a linear or branched (C₁-C₈) alkyl group, or —Si(R₅₄)(R₅₅)(R₅₆); R₅₄, R₅₅ and R₅₆ are independently selected from hydrogen, linear or branched (C₁-C₈ alkyl), linear or branched (C₁-C₈)alkoxy, or —N(R₅₇)(R₅₈); R₅₇ and R₅₈ are independently hydrogen or (C₁-C₈)alkyl; R₄₈ is hydrogen or linear or branched (C₁-C₈) hydrocarbon; W is optionally bidentate and forms a ring with the adjacent nitrogen, silicon, and/or carbon atoms and is a linear or branched (C₁-C₈) alkyl, C(R₅₉)(R₆₀), —C(R₅₉)(R₆₀)—C(R₆₁)(R₆₂)—, —C(R₅₉)(R₆₀)—C(R₆₁)(R₆₂)—C(R₆₃)(R₆₄)— or —Si(R₆₅)(R₆₆)—N(R₆₇)—Si(R₆₈)(R₆₉)—; R₅₉, R₆₀, R₆₁, R₆₂, R₆₃, R₆₄ are independently hydrogen, linear or branched (C₁-C₈)alkyl; R₆₅, R₆₆, R₆₈ and R₆₉ are hydrogen, halide, (C₁-C₈) alkyl, O(R₇₀) or N(R₇₁)(R₇₂); R₇₀ is linear or branched (C₁-C₈)alkyl; U is C(R₇₇)(R₇₈) or Si(R₇₉)Si(R₈₀); R₆₇, R₇₁, R₇₂, R₇₇, and R₇₈ are independently hydrogen or linear or branched (C₁-C₈)alkyl; and wherein the precursor compound contains at least one silicon-nitrogen or silicon-halide bond, and at least one silicon-carbon bond.

Specific examples of compounds having Formula 6, Formula 7, Formula 8, Formula 9, and Formula 10 include tris(dimethylamino)methylsilane, bis(diethylamino)methylsilane, di(isopropylamino)methylsilane, dimethylamino-(dimethoxy)methylsilane, tris(dimethylamino)(t-butyl)silane, tris(dimethylamino)phenylsilane, dimethylamino(dimethyl)cyclohexylsilane, 2-(dimethylaminosilyl)bicyclo[2.2.1]heptane, tris(dimethylamino)decylsilane, n-methyl-aza-2,2,4-trimethylsilacyclopentane, N-trimethylsilyl-aza-4-methylsilacyclopentane, N-(n-butyl)-aza-silacyclopentane, N-ethyl-aza-4-methyl-2,2-dimethoxysilacyclopentane, 1,2,2,3-tetramethyl-1,3-diaza-2-silacyclopentane, N-methyl-aza-4-methyl-2-methoxy-2-(n-butyl)silacyclopentane, bis(dimethylaminomethylsilyl)methane, bis(tris(dimethylamino)silyl)methane, bis(bis(dimethylamino)methylsilyl)methane, 1,1-bis(tris(dimethylamino)silyl)ethane, bis(bis(dimethylamino)methylsilylamino)-(dimethylamino)methylsilane, (bis(dimethylamino)methylsilylamino)-bis(dimethylamino)methylsilane, bis(bis(dimethylamino)silyl)methane, (bis(ethylamino)methylsilyl)bis(ethylamino)-methylsilane, and 1,3,5-tris(1-methylethyl)-1,3,5-triaza-2,4,6-trimethyl-2,4,6-trisilacyclohexane, 2,2,5,5-tetramethyl-1-aza-2,5-disilacyclopentane, dimethylamino(trimethoxy)silane, and n-trimethylsilyl-aza-silacyclopentane, and are shown below.

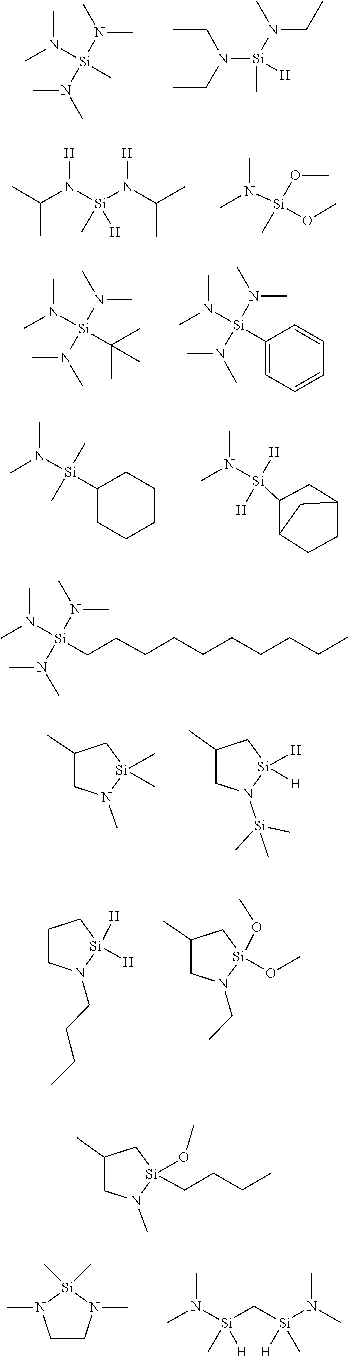

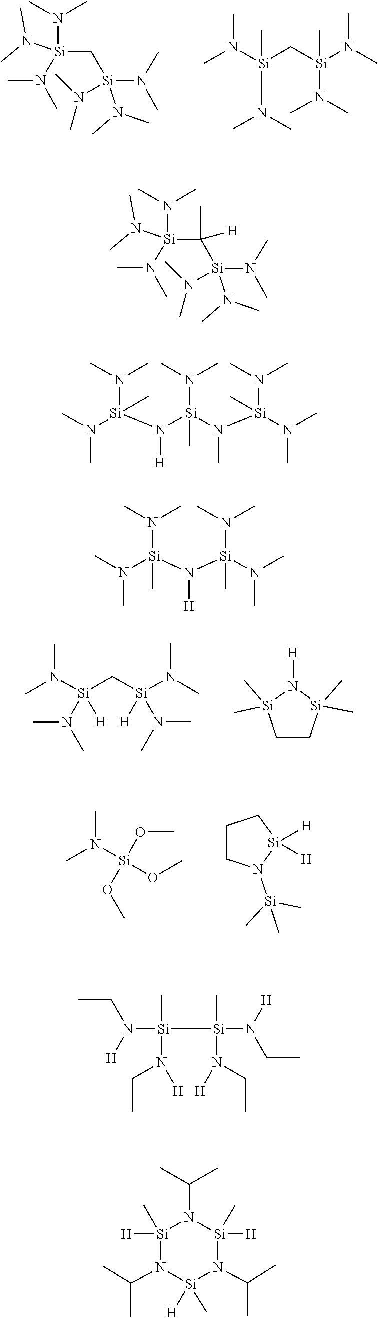

In preferred embodiments, the temperature in the reaction zone in step (g) is below about 100° C. or below about 50° C. In preferred embodiments, as described in more detail below, the deposition rate of the silicon- and carbon-containing layer is greater than about 0.3 angstroms per cycle or greater than about 0.5 angstroms per cycle, and the cycle time is less than about 120 seconds or less than about 60 seconds.

### Third Method

A third aspect of the disclosure relates to a selective thermal process for the atomic layer deposition of silicon-containing or silicon and carbon-containing films on a patterned substrate using either of the deposition processes described above. The low temperature and gentle oxidation conditions of the disclosed deposition processes are amenable to a variety of substrate passivation schemes, as is disclosed in the following ASD sequence.

Thus, a third method according to aspects of the disclosure is a method for selectively depositing a silicon-containing layer on a patterned substrate, the method comprising:
(j1) optionally performing at least one ex-situ annealing, cleaning, etching, polishing, oxidation, reduction, photolysis, UV/ozone exposure, or plasma treatment of a patterned substrate;
(j2) optionally performing one or more substrate passivation steps;
(j) introducing the patterned substrate into a reaction zone of a deposition chamber;
(k1) optionally heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate;
(k2) optionally performing one or more passivation steps;
(k) heating or cooling the reaction zone to about 0° C. to about 150° C.;
(l) performing a thermal atomic layer deposition process on the substrate to form a silicon-containing layer on the substrate by alternately exposing the substrate to low-water content hydrogen peroxide and at least one silicon-containing compound having Formula 1, Formula 2, Formula 3, Formula 4, or Formula 5 until a desired layer thickness is obtained; or
(m) performing a thermal atomic layer deposition process on the substrate to form a silicon- and -carbon-containing layer on the substrate by alternately exposing the substrate to two or more silicon-containing compounds and low-water content hydrogen peroxide; wherein at least one of the two or more silicon-containing compounds is selected from Formula 1, Formula 2, Formula 3, Formula 4, or Formula 5, and at least one of the two or more silicon-containing compounds is selected from Formula 6, Formula 7, Formula 8, Formula 9, or Formula 10; wherein at least two of the at least two silicon-containing compounds are:
delivered to the substrate simultaneously; or
delivered to the substrate sequentially, optionally separated by purges of the reaction vessel, optionally separated by exposures to low-water content hydrogen peroxide; and
(n) repeating step (m) until a desired layer thickness is reached;
wherein at least one passivation step (j2) or step (k2) is performed.

Thus, the method may also be considered as containing steps (j), (k), (1), (m), and (n), and at least one of (j2) and (k2). Step (j1) may be performed prior to or after step (j2), and step (k1) may be performed prior to or after step (k2).

In preferred embodiments, all but a final exposure of the substrate to the two or more silicon-containing compounds of step (m) covers only a fraction of the available substrate surface or is followed by an exposure to low-water content hydrogen peroxide. The final exposure of the substrate to the two or more silicon-containing compounds of step (m) may cover all of the substrate surface, or only a fraction of the substrate surface.

Steps (m) and (n) comprise an atomic layer deposition process comprising exposing the substrate to low-water content hydrogen peroxide, at least one silicon-containing precursor having Formula 1, Formula 2, Formula 3, Formula 4, or Formula 5, and at least one precursor with silicon-carbon bonds having Formula 6, Formula 7, Formula 8, Formula 9, or Formula 10. At least two of the precursors may be exposed either simultaneously for about 0.01 s to about 60 s, more preferably about 0.1 s to about 30 s, or most preferably about 1 s to about 10 s. Alternatively, at least two of the precursors may be exposed sequentially for about 0.005 s to about 30 s, more preferably about 0.01 s to about 15 s, or most preferably about 0.1 s to about 10 s for each precursor, optionally separated by purging with an inert gas such as nitrogen, helium or argon for about 0 s to about 120 s, such that all but a final exposure of the substrate to the two or more silicon-containing compounds covers only a fraction of the available substrate surface or is followed by an additional exposure of the substrate to low-water content hydrogen peroxide for about 1 s to about 120 s, preferably about 5 s to about 60 s, most preferably about 5 s to about 30 s. The details of using a sub-saturative dose of a silicon-containing precursor in order to cover only a fraction of the available substrate and thus allow reaction of a subsequent silicon-containing precursor of the sequence are discussed below. As an alternative to using a sub-saturative dose of a silicon-containing precursor, any exposure of one of the precursors of the sequence may be followed by an exposure to low-water content hydrogen peroxide, which results in the generation of a chemically reactive surface to which the next precursor of the sequence may react. In other words, the order, conditions, and duration of the exposure of the substrate to low-water content hydrogen peroxide and to the silicon-containing precursor having Formula 1, Formula 2, Formula 3, Formula 4, and/or Formula 5 and the precursor having Formula 6, Formula 7, Formula 8, Formula 9 and/or Formula 10 are highly flexible and may be optimized by routine experimentation.

In preferred embodiments, at least one passivation step (j2) and/or step (k2) meets one of the following criteria:
(i) when the substrate comprises silicon dioxide, silicon oxycarbide, silicon oxynitride, silicon carboxynitride, or germanium dioxide, exposing the patterned substrate to a compound having Formula 11 or Formula 12 to selectively passivate regions of the substrate; or
(ii) when the substrate comprises silicon nitride, titanium nitride, tantalum nitride, or germanium nitride, exposing the patterned substrate to a compound containing an aldehyde functional group to selectively passivate regions of the substrate; or
(iii) when the substrate comprises copper, cobalt, molybdenum, ruthenium, and/or tungsten, exposing the patterned substrate to an N-heterocyclic carbene or chemical compound containing sulfur or phosphorus to selectively passivate regions of the substrate; or
(iv) when the substrate comprises silicon, germanium, copper, cobalt, molybdenum, ruthenium, or tungsten, exposing the patterned substrate to a chemical compound of Formula 13 to selectively passivate regions of the substrate; or
(v) when the substrate comprises aluminum oxide, exposing the patterned substrate to a chemical compound of Formula 11, Formula 12, Formula 14, or Formula 15 to selectively passivate regions of the substrate.

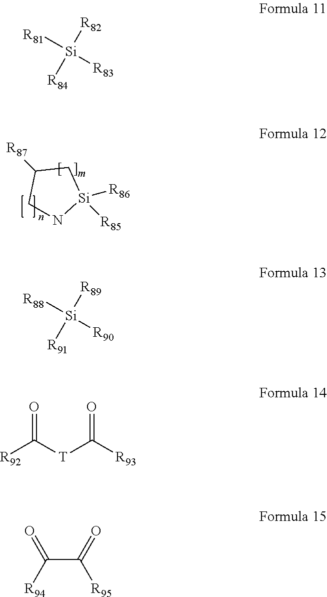

In Formulas 11-15, R₈₁, R₈₂, R₈₃, and R₈₄ are independently hydrogen, halogen, linear or branched (C₁-C₁₈)alkyl, linear or branched (C₁-C₈)alkoxy, or N(R₉₆)N(₉₇), wherein R₉₆ and R₉₇ are independently hydrogen or (C₁-C₁₈)alkyl, and at least one of R₈₁, R₈₂, R₈₃, and R₈₄ is a linear or branched (C₁-C₁₈)alkyl and at least one is N(R₉₆)R₉₇; R₈₅ and R₈₆ are hydrogen, halogen, linear or branched (C₁-C₁₈)alkyl, linear or branched (C₁-C₈)alkoxy, or N(R₉₆)(R₉₇); R₈₈, R₈₉, R₉₀ and R₉₁ are independently hydrogen or (C₁-C₁₈)alkyl, and at least one of R₈₈, R₈₉, R₉₀, or R₉₁ is hydrogen and at least one is (C₁-C₁₈)alkyl; T is linear or branched (C₁-C₄)alkyl; and R₉₂, R₉₃, R₉₄ and R₉₅ are hydrogen or (C₁-C₄)alkyl; wherein R₈₇ is hydrogen or linear or branched (C₁-C₄)alkyl; and wherein n and m are 1, 2, or 3.

The compounds having Formulas 1 to 10 have been previously described. In preferred embodiments, the temperature in the reaction zone in step (k) is below about 100° C. or below about 50° C. In preferred embodiments, as described in more detail below, the deposition rate of the silicon- and/or silicon- and carbon-containing layer is greater than about 0.3 angstroms per cycle or greater than about 0.5 angstroms per cycle, and the cycle time is less than about 120 seconds or less than about 60 seconds.

### First, Second, and Third Methods

In some embodiments of the first, second, and third aspects of this disclosure, the method may further involve the following additional steps after steps (c), (i), (1) or (n):
(d) heating or cooling the reaction zone to about 0° C. to about 800° C.; and
(e) performing at least one in-situ passivation, annealing, cleaning, etching, polishing oxidation, reduction, photolysis, UV/ozone exposure, or plasma treatment of the substrate. Step (e) may optionally include a passivation step. In this case the passivation step shall meet the same criteria as step (j2) and (k2).

In such cases, the method may further comprise repeating steps (a) or (a1) though (e) until a desired layer thickness is reached, repeating steps (f) or (f1) though (e) until a desired layer thickness is reached, or repeating steps (j) or (j2) though (e) until a desired layer thickness is reached.

In some embodiments of the first, second, and third aspects of this disclosure, the deposition steps are performed at temperatures of about 0° C. to about 150° C., more preferably about 0° C. to about 100° C., most preferably about 0° C. to about 60° C., as well as at all intervening temperatures. The preferred temperatures for the pretreatment steps depend on the nature of the step which is being performed and may be determined by routine optimization based on the ordinary skill in the art.

As used herein, the terms “substrate” or “substrate surface” refer to the base material upon which modifications or additions are made. Examples substrate surfaces related to semiconductor device manufacture include semiconductors, such as silicon, germanium, or gallium arsenide, metals, such as copper, cobalt, ruthenium, molybdenum, tungsten or their alloys, oxides, such as silicon dioxide, silicon oxycarbide, titanium dioxide, hafnium dioxide, alumina, or nitrides, such as silicon nitride, silicon carbon nitride, aluminum nitride, titanium nitride, or tantalum nitride.

Further examples of substrates include polymers or polymer films, metals, glasses, inorganic powders, organic powders, metallic powders, or powders comprising active components such as vaccines, enzymes, active pharmaceutical ingredients, drug products, catalysts, curing agents, anode, cathode or electrolytic materials; natural materials such as wood, fibers, or paper; tissue engineering scaffolds or membranes comprised of biological or synthetic materials; or reactive or temperature-sensitive materials such as biological macromolecules, organic light emitting compounds, phosphors, catalysts, perovskites or two-dimensional nanosheets such as graphene, molybdenum disulfide, tungsten disulfide or MXenes. As used herein, the term substrate may refer to a simple substrate such as a wafer, free-standing film, sheet, wire, tube, fiber or powder; a complex three-dimensional substrate such as jewelry, lenses, vials, cloth, supported catalysts, nanotubes, membranes, cloth, or tissue scaffolds; or an integrated device such as a semiconductor chip, semiconductor wafer, semiconductor panel, solar panel, display, filter, fixed catalyst bed, microelectromechanical system, battery, or medical instrument.

As used herein, a semiconductor device is an electronic component that relies on the electronic properties of a semiconductor material for its function. A semiconductor wafer is any substrate used in the manufacturing of a semiconductor device.

An active pharmaceutical ingredient, drug product, or drug substance may refer to any substance or mixture of substances intended to be the biologically active ingredient (or ‘active substance’) contained in a final medicinal product and intended to provide pharmacological activity or other direct effects.

A polymer or polymer film may refer any solid-phase particle, pellet, fiber, foam or film comprised of a polymeric material, whether as an individual object or part of a larger device. While not limiting, suitable polymeric materials include polyethylene, polypropylene, poly(ethylene teraphthalate), polystyrene, natural rubber, poly(vinyl chloride), polyester, poly(urethane), poly(tetrafluoroethylene), polycarbonate, poly(methyl methacrylate), poly(acrylonitrile), and poly(dimethylsiloxane).

Substrate surfaces may be treated or altered in various ways, including pretreatment processes such as annealing, polishing, etching, hydroxylation, oxidation, reduction, passivation, modification with chemical compounds, or plasma treatment. Additionally, new layers of other materials may be deposited onto the substrate surface. Importantly, the term “substrate surface” as used herein is flexible and may refer to the original substrate or to the surface of any newly added layers. Furthermore, the substrate surface may be substantially planar or contain complex three-dimensional structures such as vias, trenches, pillars or pores. The specific materials and processes used will determine the composition and structure of the final substrate surface.

As used herein, the “active”, “available” or “chemically reactive” regions of the substrate surface are those with chemical functionality capable of chemically reacting with the disclosed silicon precursors, low-water content hydrogen peroxide, or the chemical passivation agents of steps (j2) or (k2). While not limiting, examples of such chemical functionalities include hydroxyl groups, alkoxy groups, hydrides, amine groups, alkylamino groups, halogens, alkyl aluminum groups, thiols, phosphines and alkyl phosphine groups.

In steps (h) and (m), two or more silicon-containing precursors, at least one of which must contain a silicon-carbon bond (such as the preferred compounds having Formulas 6 to 10) and at least one of which does not contain a silicon-carbon bond (such as the preferred compounds having Formulas 1 to 5), may be exposed sequentially to the substrate surface in any order, such that all but a final exposure of the substrate to the two or more silicon-containing compounds covers only a fraction of the available substrate surface. The final exposure of the substrate to the two or more silicon-containing compounds of step (h) or step (m) may cover all of the substrate surface, or only a fraction of the substrate surface. As defined herein, “cover” means to chemically react with the chemical bonds on the substrate surface that are capable of reacting with the silicon-containing precursors. Thus, the first silicon-containing precursor may not react with all of the available chemical bonds on the substrate surface, and only the final silicon-containing precursor may react with all of the chemical bonds available on the substrate surface. Another description of this method is that the exposure doses of all but the final silicon-containing precursor are sub-saturative, while the exposure dose of the final silicon-containing precursor may be saturative or sub-saturative.

As an alternative method of implementing steps (h) and (m), the two or more silicon-containing precursors, at least one of which must contain a silicon-carbon bond (such as the preferred compounds having Formulas 6 to 10) and at least one of which does not contain a silicon-carbon bond (such as the preferred compounds having Formulas 1 to 5), may be exposed sequentially to the substrate surface with intervening exposures to low-water content hydrogen peroxide. In this case, precursors other than the last of the sequence may completely cover the entire surface, or only partially cover the entire substrate surface, with the intervening exposure to low-water content hydrogen peroxide creating an active surface with appropriate chemical bonds with which subsequent precursors of the sequence may react.

By these methods of implementing steps (h) and (m), two or more different precursors may form a mixed layer on the substrate surface. It should be understood that the deposition rate and ratios of the silicon-containing precursors in the resulting film may be controlled by manipulation of the precursor dose during its exposure to the substrate, the duration of inert gas purges between exposures of the precursors, the addition of intervening exposures of the substrate to low-water content hydrogen peroxide during the middle of the sequence, or the order of the exposures of the two or more silicon-containing precursors, and may be determined by routine optimization based on the ordinary skill in the art. Furthermore, it is within the scope of this disclosure to utilize different methods of implementing steps (h) and (m) within a single sequence, for example, exposing the substrate to two silicon-containing precursors simultaneously and a third sequentially.

As used herein, “silicon dioxide” refers to a film with an atomic composition, excluding hydrogen, of at least about 25% silicon and about 60% oxygen and at most about 2% carbon and at most about 5% nitrogen, and silicon “oxycarbide” refers to a film with an atomic composition, excluding hydrogen, of at least about 90% combined atomic percentage of silicon, oxygen, and carbon, at least about 2% carbon, and at most about 5% nitrogen. These atomic percentages are typically measured by X-ray photoelectron spectroscopy (XPS). It is noted that hydrogen is not included in these definitions as it cannot be measured by XPS.

In certain embodiments, the process used to deposit the inventive films may be described as a thermal “atomic layer deposition” or “thermal ALD” process. While not limiting, an atomic layer deposition process is comprised of alternate exposures of a substrate to one or more chemical precursor(s) which react with the substrate surface and a second chemical substance which reacts with the one or more precursors to form a film, separated by optional purges of the reaction zone with inert gas in order to prevent vapor-phase interaction of the chemical precursors and the second chemical substance. The alternating exposures of precursors and second chemical compound may be achieved by alternatively moving the precursors and second chemical compound in and out of a reaction zone containing the substrate (temporal ALD) or alternatively moving the substrate into different reaction zones, at least one of which contains one or more chemical precursors and at least one of which contains the second chemical compound (spatial ALD). The period of time that the substrate is exposed to a precursor or chemical compound is referred to as a “pulse,” and typically ranges from milliseconds to tens of seconds, as is defined herein for specific steps of the inventive process.

In certain embodiments, the processes described herein may be an “area selective” or “selective” deposition process. A selective deposition process involves the use of a patterned substrate comprised of two or more regions of differing composition, such that the deposition process deposits a film of greater thickness on one or more regions of the patterned substrate, termed “growth areas” or “growth regions,” than on one or more other regions of the patterned substrate, termed “non-growth areas” or “non-growth regions.” The “selectivity ratio” is herein defined as the ratio of film thicknesses deposited by the same process on any pair of areas or regions of the patterned substrate. The selectivity ratio between growth and non-growth surfaces in embodiments of the disclosure is at least about 2:1, at least about 5:1, or at least about 10:1.

In certain embodiments, the area selective processes described herein involve passivation of one or more substrate regions in order to inhibit film growth during the silicon-containing film deposition process. Passivation may be achieved by a variety of means known in the art, such as exposure to chemical compounds that selectively react with target regions of the substrate, blocking access to the reactive chemical surface sites of the substrate with which the silicon-containing chemical precursors would react, thus retarding film growth in that region. Such passivation may occur in a different deposition system, termed ex-situ, or the same deposition system or tool, termed in-situ, as is used to deposit the silicon-containing film, as are described in steps (j2) and (k2). Furthermore, passivation may be repeated during the film deposition process, as often as every atomic layer deposition cycle, creating an “ABC” atomic layer deposition cycle. Passivation may also be repeated after only some atomic layer deposition cycles and is commonly referred to as a “super-cycle.” For example, passivation may be repeated after every fifth cycle or after every tenth cycle, as is required by the specific process in order to maintain sufficient selectivity between growth and non-growth regions of the substrate. Both “ABC” and super-cycle processes may be created by appropriate combinations of the deposition processes (c), ((h)+(i)), (l), or ((m)+(n)) with steps ((d)+((e)).

Suitable chemical compounds for passivation of a substrate region depend on the chemical or material composition of the targeted region. Because of the low temperature and gentle oxidation conditions described herein, a variety of passivation schemes known in the art are compatible with the disclosed deposition conditions. White not limiting, suitable passivation processes may include reaction of oxides such as silicon dioxide, silicon oxycarbide, silicon oxycarbonitride, germanium dioxide with amino silanes, cyclic azasilanes, alkoxysilanes, or halogenated silanes; reaction of nitrides such as silicon nitride, titanium nitride, tantalum nitride or aluminum nitride with aldehydes; reaction of metals such as copper, cobalt, tungsten, ruthenium, or molybdenum with sulfur or phosphorus containing molecules such as alkane thiols, trialkyl phosphines, benzimidazolium N-heterocyclic carbenes, or imidazolium N-heterocyclic carbenes; reaction of metals such as copper, cobalt, tungsten, ruthenium or molybdenum as well as semiconductors such as silicon, germanium, silicon-germanium alloys and gallium-arsenide with Si—H bond containing silanes such as octylsilane or dodecylsilane; or reaction of aluminum dioxide surfaces with diketones such as acetylacetone. It should be noted that steps 02) and (k2) may comprise more than one of the aforementioned passivation processes in order to inhibit growth on more than one region of the substrate surface.

According to aspects of the disclosure, the deposition rate for the deposition steps is greater than 0.3 angstroms per cycle and the cycle time is less than 120 seconds. According to further aspects of the disclosure, the deposition rate is greater than 0.5 angstroms per cycle and the cycle time less than 60 seconds. According to further aspects of this disclosure, the deposition rate is greater than 0.6 angstroms per cycle at 30° C. and greater than 0.25 angstroms per cycle at 100° C. Thus, by employing low-water content hydrogen peroxide, very desirable deposition rates of greater than 0.3 angstroms per cycle, greater than 0.5 angstroms per cycle, and even higher may be achieved, coupled with very short cycle times, such as less than 120 second, less than 60 seconds, or even shorter. Further, these favorable deposition rates and cycle times are achieved at low temperature. For the purposes of this disclosure, the cycle time may be understood to refer to combined time of exposure for all silicon precursors, the low-water content hydrogen peroxide, and intervening purges. In the first embodiment, for example, the cycle time refers to the time for step (c) divided by the number of exposures to a silicon-containing compound such as one having Formula 1, Formula 2, Formula 3, Formula 4, or Formula 5. In the second embodiment, the cycle time refers for the time for step (h). In the third embodiment, the cycle time refers to the time for step (1) divided by the number of exposures to a compound having Formula 1, Formula 2, Formula 3, Formula 4, or Formula 5, or the time for step (m).

A variety of pre-deposition processes may be applied to the substrate in order to remove contamination, planarize, or chemically modify the surface, or modify the chemical, mechanical, or electric properties of one or more regions of the substrate. While not limiting, these may include annealing, cleaning, wet or dry etching, polishing, oxidation, reduction, photolysis, UV/ozone exposure, chemical modification, passivation or plasma treatment of the substrate and may include ex-situ processes, as steps (a₁), (f₁) or (j₁), performed in a different tool than that of the disclosed silicon-containing film deposition process, or in-situ processes, as steps (b₁), (g₁) or (k₁), performed in the same tool as the silicon-containing film deposition process. These pre-deposition processes may be done at ambient temperatures, sub-ambient temperatures such as about 10° C. or about 0° C., or at elevated temperatures such as about 100° C., about 200° C., about 400° C., or about 800° C., as suitable for the particular process. Likewise, the pre-deposition processes may be carried out under ambient atmosphere, oxidizing or reducing atmospheres, vacuum, or under inert gas as is appropriate for the specific process. The processes conditions such as temperature, pressure, and atmospheric composition of the pretreatment processes may be selected independently of those of the silicon-containing deposition process.

Correspondingly, the same set of processes, as steps (d) and (e), may occur after deposition is complete or during the middle of the deposition process in order to modify the properties of one or more components of the film or the substrate, or to prepare the substrate for subsequent processes, which may include repetition of any process disclosed herein or performance of a “super-cycle.” These processes may include ex-situ processes performed in a different tool than that of the disclosed silicon-containing film deposition process, or in-situ processes performed in the same tool as the silicon-containing film deposition process. These processes may be done at ambient temperatures, sub-ambient temperatures such as about 10° C. or about 0° C., or at elevated temperatures such as about 100° C., about 200° C., about 400° C. or about 800° C., as suitable for the particular process. Likewise, these processes may be carried out under ambient atmosphere, oxidizing or reducing atmospheres, vacuum, or under inert gas as is appropriate for the specific process. The processes conditions such as temperature, pressure, and atmospheric composition of the post-treatment processes may be selected independently of those of the silicon-containing deposition process.

Thermal annealing comprises heating the substrate under inert (nitrogen, noble gases, carbon dioxide), oxidizing (oxygen, air, ozone, hydrogen peroxide, nitrous oxide) or reducing (hydrogen, ammonia, hydrocarbon) atmospheres, at pressures ranging from about 0.01 torr to about 1000 torr and temperatures of about 20° C. to about 800° C., for about one second to about twelve hours. Thermal annealing may be supplemented by electromagnetic radiation. Such photoannealing processes utilize various forms of light, such as microwaves, infrared, visible light, ultraviolet light, x-rays or gamma rays, which may be tuned as appropriate for the excitement of chemical bonds within one or more layers of the substrate. Likewise, thermal annealing may also be supplemented with electron beams, whose energy and power are tuned as appropriate for the excitement of chemical bonds within one or more layers of the substrate.

Steps (a1), (b1), (f1), (g1), (j1) and (k1) are optional processes that may be undertaken to prepare the substrate for the atomic layer deposition processes of steps (c), (h and i), (l) or (m and n). Steps (a1), (b1), (f1), (g1), (j1) and (k1) may include one or more processes known in the art such annealing, cleaning, etching, polishing, oxidation, reduction, photolysis, UV/ozone exposure, or plasma treatment of the substrate. These processes may be independently performed before placing the substrate in the atomic layer deposition tool, termed ex-situ (steps (a1), (f1) or (j1)), or inside the atomic layer deposition reactor, termed in-situ (steps (b1), (g1) or (k1)). The temperature of any preparatory step (a1), (b1), (f1), (g1), (j1) and (k1) may be selected independently of each other or of that of the atomic layer deposition process that is defined in steps (c), (h and i), (1) or (m and n). and is not limited to the temperature ranges disclosed in steps (c), (h and i), (1) or (m and n).

Steps (c) and (1) comprise a thermal atomic layer deposition process comprising exposing the substrate to at least one silicon-containing precursor of Formula 1, Formula 2, Formula 3, Formula 4 or Formula 5 for about 0.01 s to about 60 s, optionally purging the reactor with an inert gas such as nitrogen, helium, or argon for 0 s to about 120 s, exposing the substrate to a gas stream containing low-water content hydrogen peroxide for about 1 s to about 120 s, and optionally purging the reactor with an inert gas such as nitrogen, helium, or argon for 0 s to about 120 s, or preferably comprising exposing the substrate to a silicon-containing precursor having Formula 1, Formula 2, Formula 3, Formula 4, or Formula 5 for about 0.1 s to about 20 s, optionally purging the reactor with an inert gas such as nitrogen, helium, or argon for 0 s to about 30 s, exposing the substrate to a gas stream containing low-water content hydrogen peroxide for about 5 s to about 60 s, and optionally purging the reactor with an inert gas such as nitrogen, helium, or argon for 0 s to about 30 s, or most preferably comprising exposing the substrate to a silicon-containing precursor having Formula 1, Formula 2, Formula 3, Formula 4 or Formula 5, for about 1 s to about 10 s, optionally purging the reactor with an inert gas such as nitrogen, helium, or argon for 0 s to about 20 s, exposing the substrate to a gas stream containing low-water content hydrogen peroxide for about 5 s to about 30 s, and optionally purging the reactor with an inert gas such as nitrogen, helium, or argon for 0 s to about 20 s.

Steps (h and i) and (m and n) differ from steps (c) and (1) in that two or more silicon-containing chemical precursors are delivered to the substrate during the atomic layer deposition cycle, at least one of which is a precursor having Formula 1, Formula 2, Formula 3, Formula 4, or Formula 5 without Si—C bonds, and at least one of which is a precursor having Formula 6, Formula 7, Formula 8, Formula 9, or Formula 10, which contains Si—C bonds. These precursors may be delivered simultaneously or sequentially, as described in steps (h and i) and (m and n), If the silicon-containing chemical precursors are delivered sequentially, the dosing of any precursor other than the final precursor of the sequence must be insufficient to fully saturate the available chemically reactive groups on the substrate with which the precursors are interacting, such that the second and any subsequent precursors may react with available chemically reactive groups that remain on the surface. The dosing of the two or more silicon-containing chemical precursors, whether delivered simultaneously or sequentially, may be controlled by a variety of means known in the art, such as dosing time, control of the vapor pressure of the precursor by manipulation of the precursor's temperature, precursor container design, pumping speed, control of carrier gas flow rates, restriction orifices, and throttling valves.

When the substrate is a patterned substrate having growth and non-growth surfaces, the selectivity ratio between growth and non-growth surfaces in embodiments of the disclosure is at least about 2:1, at least about 5:1, or at least about 10:1.

The invention will now be described in connection with the following, non-limited examples.

### Example 1: Low Temperature Deposition of Silicon Dioxide Using Low-Water Content Hydrogen Peroxide at 23° C. and an Aminosilane

A silicon wafer coupon with 1000 nm of thermally-grown silicon dioxide was placed in a reaction chamber at 23° C. The coupon was exposed to one minute of oxygen plasma in order to remove adventitious contamination, and then 25 ALD cycles of sequential exposures to tris(dimethylamino)silane (7 seconds) and low-water content hydrogen peroxide (20 seconds) delivered by a RASIRC BRUTE hydrogen peroxide delivery system, separated by 5 second purges with nitrogen gas were performed. Film growth of 1.0 angstrom per 37 second cycle was observed by in-situ ellipsometry. A film composition of silicon dioxide with less than 1% carbon and 1% nitrogen was confirmed by x-ray photoelectron spectroscopy (XPS). The exposure of the substrate to hydrogen peroxide was determined to be no greater than 3.35×10⁻⁶ Langmuirs per atomic layer deposition cycle.

### Example 2: Low Temperature Deposition of Silicon Dioxide Using Low-Water Content Hydrogen Peroxide at 30° C. and a Chloroaminosilane

A silicon wafer coupon with 1.7 nm native silicon dioxide was placed in a reaction chamber at 30° C. The coupon was exposed to one minute of oxygen plasma in order to remove adventitious contamination, and then 500 ALD cycles of sequential exposures to tris(dimethylamino)chlorosilane (5 seconds) and low-water content hydrogen peroxide (20 seconds) delivered by a RASIRC BRUTE hydrogen peroxide delivery system, separated by 5 second purges with nitrogen gas were performed. Film growth of 0.31 angstrom per 35 second cycle was observed by in-situ ellipsometry.

### Example 3 (Comparative): Low Temperature Deposition of Silicon Dioxide Using 30% Hydrogen Peroxide in Water and an Aminosilane at 30° C.

A silicon wafer coupon with 1000 nm of thermally-grown silicon dioxide was placed in a reaction chamber at 30° C. The coupon was exposed to one minute of nitrogen plasma in order to remove adventitious contamination, and then 100 ALD cycles of sequential exposures to tris(dimethylamino)silane (5 seconds) and a 30% solution of hydrogen peroxide in water (20 seconds) delivered from a bubbler, separated by 5 second purges with nitrogen gas were performed. Film growth of 0.004 angstrom per 35 second cycle was observed by in-situ ellipsometry. This example demonstrates the importance of employing low-water content hydrogen peroxide, as the employed solution containing 30% hydrogen peroxide (70% water) resulted in nearly no film growth at 30° C.

### Example 4: Low Temperature Deposition of Silicon Dioxide Using Low-Water Content Hydrogen Peroxide and an Aminosilane at 30° C.

A silicon wafer coupon with 1.7 nm of native silicon dioxide was placed in a reaction chamber at 30° C. The coupon was exposed to one minute of oxygen plasma in order to remove adventitious contamination, and then 50 ALD cycles of sequential exposures to tris(dimethylamino)silane (3 seconds) and low-water content hydrogen peroxide (20 seconds) delivered by a RASIRC BRUTE hydrogen peroxide delivery system, separated by a 10 second purge and 5 second purge respectively with nitrogen gas were performed. Film growth of 0.88 angstrom per 38 second cycle was observed by in-situ ellipsometry.

### Comparative Example 5 (Comparative): Low Temperature Deposition of Silicon Dioxide Using Low-Water Content Hydrogen Peroxide and Water Sequentially

A silicon wafer coupon with 1.7 nm of native silicon dioxide was placed in a reaction chamber at 30° C. The coupon was exposed to one minute of oxygen plasma in order to remove adventitious contamination, and then 550 ALD cycles of sequential exposures to tris(dimethylamino)silane (3 seconds), low-water content hydrogen peroxide (20 seconds) delivered by a RASIRC BRUTE hydrogen peroxide delivery system and water (5 seconds), separated by purges with nitrogen gas of 5 seconds, 5 seconds and 0 seconds respectively, were performed. Film growth of 0.77 angstrom per 38 second cycle was observed by in-situ ellipsometry. Thus, it was observed that pulsing water before the silane interfered with the silane absorption, slowing growth by 12% relative to Example 4, and further demonstrating the need for low-water content hydrogen peroxide.

### Example 6: Passivation of a Silicon Dioxide Substrate Towards Low Temperature Deposition of Silicon Dioxide Using Low-Water Content Hydrogen Peroxide and an Aminosilane at 30° C.

A silicon wafer coupon with 1000 nm of thermally-grown silicon dioxide was placed in a reaction chamber at 30° C. The coupon was exposed to one minute of oxygen plasma in order to remove adventitious contamination and then exposed to a ten second pulse of n-methyl-aza-2,2,4-trimethylsilacyclopentane. Immediate growth of a 0.38 nm thick passivation layer was observed. Subsequently, 75 ALD cycles of sequential exposures to tris(dimethylamino)silane (5 seconds) and low-water content hydrogen peroxide (20 seconds) delivered by a RASIRC BRUTE hydrogen peroxide delivery system, separated by 15 second purges with nitrogen gas were performed. Additional film growth over 75 cycles was 0.19 nanometers as determined by in-situ ellipsometry and confirmed by XPS. This example demonstrates silicon dioxide as a non-growth surface.

### Example 7: Non-Passivation of a Cobalt Substrate Towards Low Temperature Deposition of

Silicon Dioxide using Low-water Content Hydrogen Peroxide and an Aminosilane at 30° C. A silicon wafer coupon with a surface layer of 50 nm of sputter coated cobalt was placed in a reaction chamber at 30° C. The coupon was exposed to one minute of oxygen plasma in order to remove adventitious contamination and then exposed to a ten second pulse of n-methyl-aza-2,2,4-trimethylsilacyclopentane. Subsequently, 75 ALD cycles of sequential exposures to tris(dimethylamino)silane (5 seconds) and low-water content hydrogen peroxide (20 seconds) delivered by a RASIRC BRUTE hydrogen peroxide delivery system, separated by 15 second purges with nitrogen gas were performed. A film of approximately four nanometers of thickness and a composition of silicon dioxide with less than 1% carbon and 1% nitrogen was confirmed by x-ray photoelectron spectroscopy (XPS), resulting in a selectivity ratio of Example 7 to Example 6 of about 21.

### Example 8: Passivation of an Aluminum Oxide Substrate Towards Low Temperature Deposition Of Silicon Dioxide Using Low-Water Content Hydrogen Peroxide and an Aminosilane at 30° C.

A silicon wafer coupon with 100 nm of alumina coated by physical vapor deposition was placed in a reaction chamber at 30° C. The coupon was exposed to one minute of nitrogen plasma and 30 seconds of hydrogen peroxide in order to remove adventitious contamination and then exposed to a ten second pulse of n-methyl-aza-2,2,4-trimethylsilacyclopentane. Immediate growth of a 0.40 nm thick passivation layer was observed. Subsequently, 150 ALD cycles of sequential exposures to tris(dimethylamino)silane (3 seconds) and low-water content hydrogen peroxide (20 seconds) delivered by a RASIRC BRUTE hydrogen peroxide delivery system, separated by nitrogen gas purges of 10 s and 5 s respectively were performed. Additional film growth over 150 cycles was 2.3 nanometers as determined by in-situ ellipsometry and no growth was observed for the first 86 cycles. This example demonstrates an aluminum oxide (AlOₓ) surface as a non-growth surface.

### Example 9: Non-Passivation of a Hydrogen-Terminated Silicon Substrate Towards Low Temperature Deposition of Silicon Dioxide Using Low-Water Content Hydrogen Peroxide and an Aminosilane at 30° C.

A silicon wafer coupon with a 1.7 native oxide layer was etched with 100:1 HF buffer solution for 5 minutes, rinsed with water and dried with nitrogen. The coupon was placed in a reaction chamber at 30° C. and held at that temperature for 90 minutes to remove absorbed water from the surface. The coupon was then exposed to a ten second pulse of n-methyl-aza-2,2,4-trimethylsilacyclopentane, where growth of a passivation layer of less than one angstrom was observed. Subsequently, 150 ALD cycles of sequential exposures to tris(dimethylamino)silane (3 seconds) and low-water content hydrogen peroxide (20 seconds) delivered by a RASIRC BRUTE hydrogen peroxide delivery system, separated by nitrogen gas purges of 10 s and 5 s respectively were performed. Additional film growth over 150 cycles was 8.7 nanometers and over the first 86 cycles was 5.3 nanometers as determined by in-situ ellipsometry and growth began on the first cycle. This example demonstrates Si(H) as a growth surface. Relative to Example 8, the selectivity ratio was about 3.8 after 150 cycles and over 100 after 86 cycles.

### Example 10: Non-Passivation of a Silicon-Nitride Substrate Towards Low Temperature Deposition of Silicon Dioxide Using Low-Water Content Hydrogen Peroxide and an Aminosilane at 30° C.

A silicon wafer coupon with a 100 nm thick SiN layer deposited by physical vapor deposition was etched with 100:1 HF buffer solution for 5 minutes, rinsed with water and dried with nitrogen. The coupon was placed in a reaction chamber at 30° C. and held at that temperature for 90 minutes to remove absorbed water from the surface. The coupon was then exposed to a ten second pulse of n-methyl-aza-2,2,4-trimethylsilacyclopentane, where growth of a passivation layer of about one angstrom was observed. Subsequently, 50 ALD cycles of sequential exposures to tris(dimethylamino)silane (3 seconds) and low-water content hydrogen peroxide (20 seconds) delivered by a RASIRC BRUTE hydrogen peroxide delivery system, separated by nitrogen gas purges of 10 s and 5 s respectively were performed. Additional film growth over 50 cycles was 2.24 nanometers as determined by in-situ ellipsometry and growth began on the fifth cycle. This examples demonstrates the use of silicon nitride as a growth surface. Relative to Example 8, the selectivity ratio after 50 cycles was greater than 100.

### Example 11: Deposition of Silicon Dioxide on Acetaminophen Powder Using Low-Water Content Hydrogen Peroxide and an Aminosilane at 30° C.

Acetaminophen powder was placed in an aluminum pan inside reaction chamber at 30° C. The powder was exposed to 100 ALD cycles of sequential exposures to tris(dimethylamino)silane (3 seconds) and low-water content hydrogen peroxide (20 seconds) delivered by a RASIRC BRUTE hydrogen peroxide delivery system, separated by 5 second purges with nitrogen gas. The powder was removed from the reaction chamber and mixed. The deposition and mixing process then were repeated two additional times, for a total of 300 ALD cycles, resulting in a coating of silicon dioxide of approximately 18.5 nm as determined by in-situ ellipsometry of a witness silicon wafer coupon. The presence 1.1 atom percent silicon on the acetaminophen powder was confirmed by scanning electron microscopy (SEM) with energy dispersive X-ray (EDX) spectroscopy. The acetaminophen powder was further analyzed by liquid chromatography and found to have retained a purity of greater than 98%

### Example 12: Deposition of Silicon Dioxide on PET Polymer Film Using Low-Water Content Hydrogen Peroxide and an Aminosilane at 30° C.

A free-standing polyethylene terephthalate (PET) film was placed into a reaction chamber at 30° C. The film was exposed to 300 ALD cycles of sequential exposures to tris(dimethylamino)silane (3 seconds) and low-water content hydrogen peroxide (20 seconds) delivered by a RASIRC BRUTE hydrogen peroxide delivery system, separated by 5 second purges with nitrogen gas, resulting in a coating of silicon dioxide of approximately 18.5 nm as determined by in-situ ellipsometry of a witness silicon wafer coupon. The presence of 0.69 atom percent silicon on the PET was confirmed by scanning electron microscopy (SEM) with energy dispersive X-ray (EDX) spectroscopy and XPS.

### Example 13: Low Temperature Deposition of Silicon Oxycarbide Using Low-Water Content Hydrogen Peroxide and Two Aminosilanes at 30° C.

A silicon wafer coupon with 1000 nm of thermally-grown silicon dioxide was placed in a reaction chamber at 30° C. The coupon was exposed to one minute of oxygen plasma in order to remove adventitious contamination, and then 300 ALD cycles of sequential exposures to tris(dimethylamino)methylsilane (1 second), tris(dimethylamino)silane (5 seconds) and low-water content hydrogen peroxide (20 seconds) delivered by a RASIRC BRUTE hydrogen peroxide delivery system, separated by 5 second purges with nitrogen gas were performed. Film growth of 0.37 angstrom per 41 second cycle was observed by in-situ ellipsometry. A film composition of silicon oxycarbide with 7.1% carbon and 1.7% nitrogen was confirmed by x-ray photoelectron spectroscopy (XPS). It is noted that this is an example of a cycle employing a precursor having Formula 6 (sub-saturative), then a precursor having Formula 1 (saturative) and then low-water hydrogen peroxide, spaced by purges. The short pulse time of the Formula 6 compound leaves room on the substrate surface for the Formula 1 compound to react. Thus, both precursors are present when the peroxide is introduced, and a mixed layer formed. As the peroxide cannot easily cleave the methyl group, most or all of it is retained in the film.

It is understood, therefore, that this invention is not limited to the particular embodiments disclosed, but it is intended to cover modifications within the spirit and scope of the present invention as defined by the appended claims.

We claim:

1. A method for depositing a silicon- and oxygen-containing layer on a substrate, the method comprising:
(a) introducing a substrate into a reaction zone of a deposition chamber;
(b) heating or cooling the reaction zone to about 0° C. to about 150° C.; and
(c) performing a thermal atomic layer deposition process on the substrate to form a silicon- and oxygen-containing layer on the substrate by alternately exposing the substrate to at least one silicon-containing compound and low-water content hydrogen peroxide until a desired layer thickness is obtained.

2. The method according to claim 1, further comprising prior to step (a):
(a1) performing at least one ex-situ annealing, cleaning, etching, polishing, oxidation, reduction, photolysis, UV/ozone exposure, chemical modification, or plasma treatment of the substrate.

3. The method according to claim 1, further comprising after step (a) and prior to step (b):
(b1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

4. The method according to claim 1, wherein the at least one silicon-containing compound has Formula 1, Formula 2, Formula 3, Formula 4, or Formula 5: 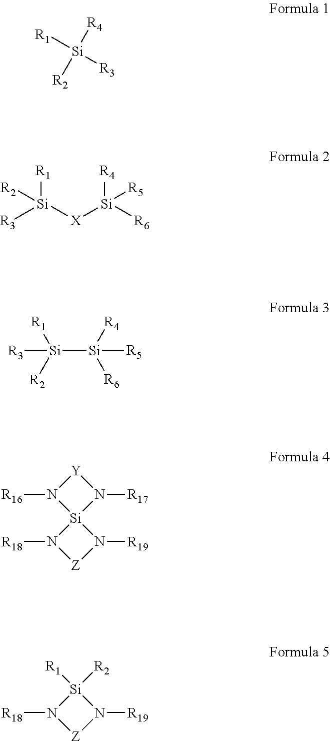
wherein R₁, R₂, R₃, R₄, R₅, R₆, R₂₆, R₂₇, R₂₉, and R₃₀ are independently selected from hydrogen, halogen, OR₇ or N(R₈)(R₉); X is O or N(R₁₀); Y and Z are —C(R₂₀)(R₂₁), —C(R₂₀)(R₂₁)—C(R₂₂)(R₂₃)—, —C(R₂₀)(R₂₁)—C(R₂₂)(R₂₃)—C(R₂₄)(R₂₅)— or —Si(R₂₆)(R₂₇)—N(R₂₈)—Si(R₂₉)R(₃₀)—, Y and Z are optionally bidentate and form a ring with the adjacent nitrogen atoms; R₇ is a linear or branched (C₁-C₈) alkyl group, or —Si(R₁₁)(R₁₂)(R₁₃), R₁₁, R₁₂ and R₁₃ are independently selected from hydrogen, halide, linear or branched (C₁-C₈)alkoxy, or —N(R₁₄)(R₁₅), R₁₄ and R₁₅ are independently hydrogen or linear or branched (C₁-C₈)alkyl; R₈, R₉, R₁₀, R₁₆, R₁₇, R₁₈, R₁₉ and R₂₈ are independently hydrogen, linear or branched (C₁-C₈) alkyl groups or Si(R₃₁)(R₃₂)(R₃₃), R₃₁, R₃₂ and R₃₃ are hydrogen, (C₁-C₈)alkyl, or N(R₃₄)(R₃₅), R₃₄ and R₃₅ are hydrogen or (C₁-C₈)alkyl; R₂₀, R₂₁, R₂₂, R₂₃, R₂₄, and R₂₅ are hydrogen, vinyl, allyl, or linear or branched (C₁-C₄) alkyl; and wherein at least half of the bonds to silicon atoms comprise Si—N bonds or silicon halide bonds.

5. The method according to claim 1, wherein the at least one silicon-containing compound is tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3-diaza-2-silacyclopentane, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, penta(dimethylamino)disilane, bis(t-butylamino)silane, bis(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, hexa(dimethylamino)silazane, tetrachlorosilane, tris(dimethylamino)chlorosilane, 1,2-bis(dimethylamino)disilane, hexakis(ethylamino)disilane, tris(ethylaminosilane), tri(isopropylamino)silane, tris(n-propylamino)silane, tris(t-butyl)aminosilane, tris(n-butylaminosilane), tris(sec-butylaminosilane), tris(diethylamino)silane, tris(diisopropyl)aminosilane, tris(di-n-propyl)aminosilane, tris(di-t-butylamino)silane, tris(di-n-butylamino)silane or tris(di-sec-butylamino)silane.

6. The method according to claim 5, wherein the at least one silicon-containing compound is tris(dimethylamino)silane, tris(dimethylamino)chlorosilane, tris(diethylamino)silane, tris(ethylamino)silane, or tris(isopropylamino)silane.

7. The method according to claim 1, wherein a temperature of the reaction zone in step (b) is below about 100° C.

8. The method according to claim 7, wherein the temperature of the reaction zone in step (b) is below about 50° C.

9. The method according to claim 1, wherein the hydrogen peroxide contains less than about 30 weight percent water.

10. The method according to claim 9, wherein the hydrogen peroxide contains less than about 20 weight percent water.

11. The method according to claim 10, wherein the hydrogen peroxide contains less than about 10 weight percent water.

12. The method according to claim 1, wherein a deposition rate of the silicon- and oxygen-containing layer is greater than about 0.3 angstroms per cycle and a cycle time is less than about 120 seconds.

13. The method according to claim 12, wherein the deposition rate of the silicon- and oxygen-containing layer is greater than about 0.5 angstroms per cycle and a cycle time less than about 60 seconds.

14. The method according to claim 1, wherein after step (c), the method further comprises:
(d) heating or cooling the reaction zone to about 0° C. to about 800° C.; and
(e) performing at least one in-situ passivation, annealing, cleaning, etching, polishing, oxidation, reduction, photolysis, UV/ozone exposure, or plasma treatment of the substrate.

15. The method according to claim 14, further comprising after step (e);
(o) Repeating steps (a) or (a1) through (e) until a desired layer thickness is reached.

16. The method of claim 1, wherein the substrate comprises a semiconductor device, an active pharmaceutical ingredient, a drug product, a polymer, or a polymer film.

17. A method for depositing a silicon- and -carbon-containing layer on a substrate, the method comprising:
(f) introducing a substrate into a reaction zone of a deposition chamber;
(g) heating or cooling the reaction zone to about 0° C. to about 150° C.; and
(h) performing a thermal atomic layer deposition process on the substrate to form a silicon- and carbon-containing layer on the substrate by alternately exposing the substrate to two or more silicon-containing compounds and low-water content hydrogen peroxide; wherein at least one of the two or more silicon-containing compounds has Formula 1, Formula 2, Formula 3, Formula 4, or Formula 5, and at least one of the two or more silicon-containing compounds has Formula 6, Formula 7, Formula 8, Formula 9, or Formula 10; wherein at least two of the two or more silicon-containing compounds are:
delivered to the substrate simultaneously; or
delivered to the substrate sequentially, optionally separated by purges of the reaction zone, optionally separated by exposures to low-water content hydrogen peroxide, and
(i) repeating step (h) until a desired layer thickness is obtained: 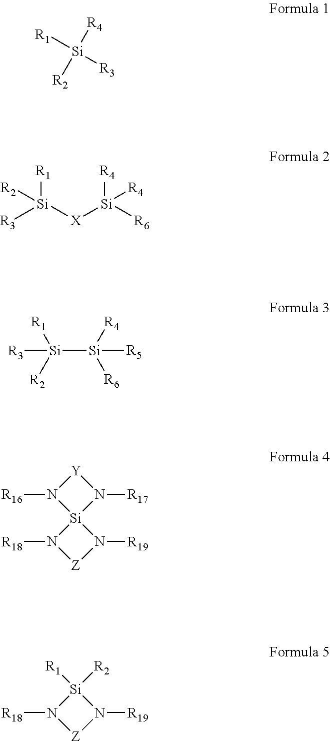
wherein R₁, R₂, R₃, R₄, R₅, R₆, R₂₆, R₂₇, R₂₉, and R₃₀ are independently selected from hydrogen, halogen, OR₇ or N(R₈)(R₉); X is O or N(R₁₀); Y and Z are —C(R₂₀)(R₂₁), —C(R₂₀)(R₂₁)—C(R₂₂)(R₂₃)—, —C(R₂₀)(R₂₁)—C(R₂₂)(R₂₃)—C(R₂₄)(R₂₅)— or —Si(R₂₆)(R₂₇)—N(R₂₈)—Si(R₂₉)R(₃₀)—, Y and Z are optionally bidentate and form a ring with the adjacent nitrogen atoms; R₇ is a linear or branched (C₁-C₈) alkyl group, or —Si(R₁₁)(R₁₂)(R₁₃), R₁₁, R₁₂ and R₁₃ are independently selected from hydrogen, halide, linear or branched (C₁-C₈)alkoxy, or —N(R₁₄)(R₁₅), R₁₄ and R₁₅ are independently hydrogen or linear or branched (C₁-C₈)alkyl; R₈, R₉, R₁₀, R₁₆, R₁₇, R₁₈, R₁₉ and R₂₈ are independently hydrogen, linear or branched (C₁-C₈) alkyl groups or Si(R₃₁)(R₃₂)(R₃₃), R₃₁, R₃₂ and R₃₃ are hydrogen, (C₁-C₈)alkyl, or N(R₃₄)(R₃₅), R₃₄ and R₃₅ are hydrogen or (C₁-C₈)alkyl; R₂₀, R₂₁, R₂₂, R₂₃, R₂₄, and R₂₅ are hydrogen, vinyl, allyl, or linear or branched (C₁-C₄) alkyl; and wherein at least half of the bonds to silicon atoms comprise Si—N bonds or silicon halide bonds; 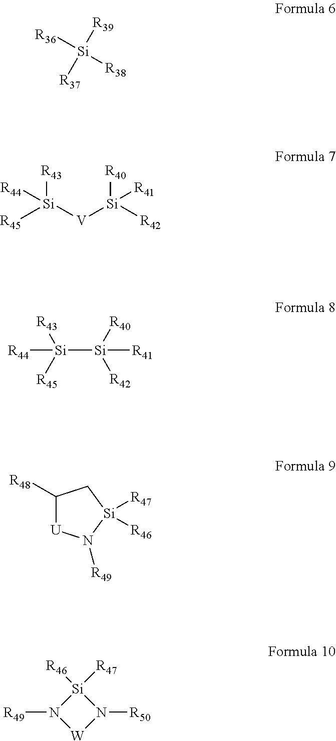
wherein R₃₆, R₃₇, R₃₈, R₃₉, R₄₀, R₄₁, R₄₂, R₄₃, R₄₄, R₄₅, R₄₆, R₄₇, R₇₉, and R₈₀ are independently selected from hydrogen, halogen, linear or branched (C₁-C₁₈) alkyl, linear or branched (C₁-C₁₈) alkoxy, vinyl, allyl, butenyl, phenyl, tolyl, cyclohexyl, cyclooctyl, or norbornyl, or N(R₅₁)(R₅₂); V is optionally bidentate and is 0, N(R₅₃), C(R₇₃)(R₇₄), linear or branched (C₁-C₈) alkyl, or —C(R₇₃)(R₇₄)—C(R₇₅)(R₇₆)— wherein C₇₃, C₇₄, C₇₅ and C₇₆ are hydrogen or linear or branched (C₁-C₈)alkyl; R₄₉, R₅₀, R₅₁, R₅₂ and R₅₃ are hydrogen, a linear or branched (C₁-C₈) alkyl group, or —Si(R₅₄)(R₅₅)(R₅₆); R₅₄, R₅₅ and R₅₆ are independently selected from hydrogen, linear or branched (C₁-C₈ alkyl), linear or branched (C₁-C₈)alkoxy, or —N(R₅₇)(R₅₈); R₅₇ and R₅₅ are independently hydrogen or (C₁-C₈)alkyl; R₄₈ is hydrogen or linear or branched (C₁-C₈) hydrocarbon; W is optionally bidentate and forms a ring with the adjacent nitrogen, silicon, and/or carbon atoms and is a linear or branched (C₁-C₈) alkyl, C(R₅₉)(R₆₀), —C(R₅₉)(R₆₀)—C(R₆₁)(R₆₂)—, —C(R₅₉)(R₆₀)—C(R₆₁)(R₆₂)—C(R₆₃)(R₆₄)— or —Si(R₆₅)(R₆₆)—N(R₆₇)—Si(R₆₈)(R₆₉)—; R₅₉, R₆₀, R₆₁, R₆₂, R₆₃, R₆₄ are independently hydrogen, linear or branched (C₁-C₈)alkyl; R₆₅, R₆₆, R₆₈ and R₆₉ are hydrogen, halide, (C₁-C₈) alkyl, O(R₇₀) or N(R₇₁)(R₇₂); R₇₀ is linear or branched (C₁-C₈)alkyl; U is C(R₇₇)(R₇₈) or Si(R₇₉)Si(R₈₀); R₆₇, R₇₁, R₇₂, R₇₇, and R₇₈ are independently hydrogen or linear or branched (C₁-C₈)alkyl; and wherein the precursor compound contains at least one silicon-nitrogen or silicon-halide bond, and at least one silicon-carbon bond.

18. The method according to claim 17, wherein all but a final exposure of the substrate to the two or more silicon-containing compounds covers only a fraction of the available substrate surface or is followed by an exposure to low-water content hydrogen peroxide.

19. The method according to claim 17, further comprising prior to step (f):
(f1) performing at least one ex-situ annealing, cleaning, etching, polishing, oxidation, reduction, photolysis, UV/ozone exposure, chemical modification, or plasma treatment of the substrate.

20. The method according to claim 17, further comprising after step (f) and prior to step (g):
(g1) heating or cooling the reaction zone to about 0° C. to about 800° C. and performing at least one in-situ annealing, cleaning, etching, polishing, oxidation, reduction, photolysis, UV/ozone exposure, chemical modification, or plasma treatment of the substrate.

21. The method according to claim 17, wherein at least one of the silicon-containing compounds having Formula 1, Formula 2, Formula 3, Formula 4, or Formula 5 is tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3-diaza-2-silacyclopentane, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, penta(dimethylamino)disilane, bis(t-butylamino)silane, bis(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, hexa(dimethylamino)silazane, tetrachlorosilane, tris(dimethylamino)chlorosilane, 1,2-bis(dimethylamino)disilane, hexakis(ethylamino)disilane, tris(ethylaminosilane), tri(isopropylamino)silane, tris(n-propylamino)silane, tris(t-butyl)aminosilanes, tris(n-butylaminosilane), tris(sec-butylaminosilane), tris(diethylamino)silane, tris(diisopropyl)aminosilane, tris(di-n-propyl)aminosilane, tris(di-t-butylamino)silane, tris(di-n-butylamino)silane or tris(di-sec-butylamino)silane.

22. The method according to claim 21, wherein at least one of the silicon-containing compounds having Formula 1, Formula 2, Formula 3, Formula 4, or Formula 5 is tris(dimethylamino)silane, tris(dimethylamino)chlorosilane, tris(diethylamino)silane, tris(ethylamino)silane, or tris(isopropylamino)silane.

23. The method according to claim 17, wherein at least one of the silicon-containing compounds having Formula 6, Formula 7, Formula 8, Formula 9, or Formula 10 is tris(dimethylamino)methylsilane, bis(diethylamino)methylsilane, di(isopropylamino)methylsilane, dimethylamino-(dimethoxy)methylsilane, tris(dimethylamino)(t-butyl)silane, tris(dimethylamino)phenylsilane, dimethylamino(dimethyl)cyclohexylsilane, 2-(dimethylaminosilyl)bicyclo[2.2.1]heptane, tris(dimethylamino)decylsilane, n-methyl-aza-2,2,4-trimethylsilacyclopentane, n-trimethylsilyl-aza-4-methylsilacyclopentane, n-(n-butyl)-aza-silacyclopentane, n-ethyl-aza-4-methyl-2,2-dimethoxysilacyclopentane, 1,2,2,3-tetramethyl-1,3-diaza-2-silacyclopentane, N-methyl-aza-4-methyl-2-methoxy-2-(n-butyl)silacyclopentane, bis(dimethylaminomethylsilyl)methane, bis(tris(dimethylamino)silyl)methane, bis(bis(dimethylamino)methylsilyl)methane, 1,1-bis(tris(dimethylamino)silyl)ethane, bis(bis(dimethylamino)methylsilylamino)-(dimethylamino)methylsilane, (bis(dimethylamino)methylsilylamino)-bis(dimethylamino)methylsilane, bis(bis(dimethylamino)silyl)methane, (bis(ethylamino)methylsilyl)bis(ethylamino)-methylsilane, and 1,3,5-tris(1-methylethyl)-1,3,5-triaza-2,4,6-trimethyl-2,4,6-trisilacyclohexane, 2,2,5,5-tetramethyl-1-aza-2,5-disilacyclopentane, dimethylamino(trimethoxy)silane, or n-trimethylsilyl-aza-silacyclopentane

24. The method according to claim 23, wherein at least one of the silicon-containing compounds having Formula 6, Formula 7, Formula 8, Formula 9, or Formula 10 is tris(dimethylamino)methylsilane, bis(tris(dimethylamino)silyl)methane, n-methyl-aza-2,2,4-trimethylsilacyclopentane or bis(dimethylaminomethylsilyl)methane.

25. The method according to claim 17, wherein a temperature of the reaction zone in step (g) is below about 100° C.

26. The method according to claim 25, wherein the temperature of the reaction zone in step (g) is below about 50° C.

27. The method according to claim 17, wherein the hydrogen peroxide contains less than about 30 weight percent water.

28. The method according to claim 27, wherein the hydrogen peroxide contains less than about 20 weight percent water.

29. The method according to claim 28, wherein the hydrogen peroxide contains less than about 10 weight percent water.

30. The method according to claim 17, wherein a deposition rate of the silicon- and carbon-containing layer is greater than about 0.3 angstroms per cycle a cycle time is less than about 120 seconds.

31. The method according to claim 30, wherein the deposition rate of the silicon- and carbon-containing layer is greater than about 0.5 angstroms per cycle and cycle time is less than about 60 seconds.

32. The method according to claim 17, wherein after step (i), the method further comprises:
(d) heating or cooling the reaction zone to about 0° C. to about 800° C.; and
(e) performing at least one in-situ passivation, annealing, cleaning, etching, polishing, oxidation, reduction, photolysis, UV/ozone exposure, or plasma treatment of the substrate.

33. The method according to claim 32, further comprising after step (e);
(o) repeating steps (f) or (f1) through (e) until a desired layer thickness is reached.

34. The method according to claim 17, wherein the substrate comprises a semiconductor device, an active pharmaceutical ingredient, a drug product, a polymer, or a polymer film.

35. A method for selectively depositing a silicon-containing layer on a patterned substrate, the method comprising:
(j) introducing a patterned substrate into a reaction zone of a deposition chamber;
(k) heating or cooling the reaction zone to about 0° C. to about 150° C.;
(l) performing a thermal atomic layer deposition process on the substrate to form a silicon-containing layer on the substrate by alternately exposing the substrate to low-water content hydrogen peroxide and at least one silicon-containing compound having Formula 1, Formula 2, Formula 3, Formula 4, or Formula 5 until a desired layer thickness is obtained; or
(m) performing a thermal atomic layer deposition process on the substrate to form a silicon- and carbon-containing layer on the substrate by alternately exposing the substrate to two or more silicon-containing compounds and low-water content hydrogen peroxide; wherein at least one of the two or more silicon-containing compounds has Formula 1, Formula 2, Formula 3, Formula 4, or Formula 5, and at least one of the two or more silicon-containing compounds has Formula 6, Formula 7, Formula 8, Formula 9, or Formula 10; wherein at least two of the two or more silicon-containing compounds are:
delivered to the substrate simultaneously; or
delivered to the substrate sequentially, optionally separated by purges of the reaction zone, optionally separated by exposures to low-water content hydrogen peroxide, and
(n) repeating step (m) until a desired layer thickness is reached;
wherein the method further comprises:
prior to step (j): (j2) performing one or more substrate passivation steps; and/or
prior to step (k): (k2) performing one or more substrate passivation steps; 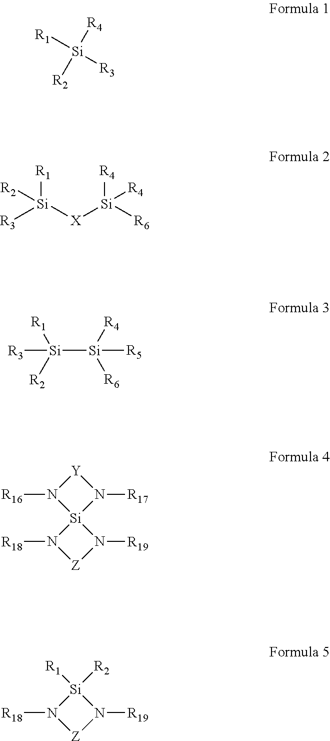
wherein R₁, R₂, R₃, R₄, R₅, R₆, R₂₆, R₂₇, R₂₉, and R₃₀ are independently selected from hydrogen, halogen, OR₇ or N(R₈)(R₉); X is O or N(R₁₀); Y and Z are —C(R₂₀)(R₂₁), —C(R₂₀)(R₂₁)—C(R₂₂)(R₂₃)—, —C(R₂₀)(R₂₁)—C(R₂₂)(R₂₃)—C(R₂₄)(R₂₅)— or —Si(R₂₆)(R₂₇)—N(R₂₈)—Si(R₂₉)R(₃₀)—, Y and Z are optionally bidentate and form a ring with the adjacent nitrogen atoms; R₇ is a linear or branched (C₁-C₈) alkyl group, or —Si(R₁₁)(R₁₂)(R₁₃), R₁₁, R₁₂ and R₁₃ are independently selected from hydrogen, halide, linear or branched (C₁-C₈)alkoxy, or —N(R₁₄)(R₁₅), R₁₄ and R₁₅ are independently hydrogen or linear or branched (C₁-C₈)alkyl; R₈, R₉, R₁₀, R₁₆, R₁₇, R₁₈, R₁₉ and R₂₈ are independently hydrogen, linear or branched (C₁-C₈) alkyl groups or Si(R₃₁)(R₃₂)(R₃₃), R₃₁, R₃₂ and R₃₃ are hydrogen, (C₁-C₈)alkyl, or N(R₃₄)(R₃₅), R₃₄ and R₃₅ are hydrogen or (C₁-C₈)alkyl; R₂₀, R₂₁, R₂₂, R₂₃, R₂₄, and R₂₅ are hydrogen, vinyl, allyl, or linear or branched (C₁-C₄) alkyl; and wherein at least half of the bonds to silicon atoms comprise Si—N bonds or silicon halide bonds; 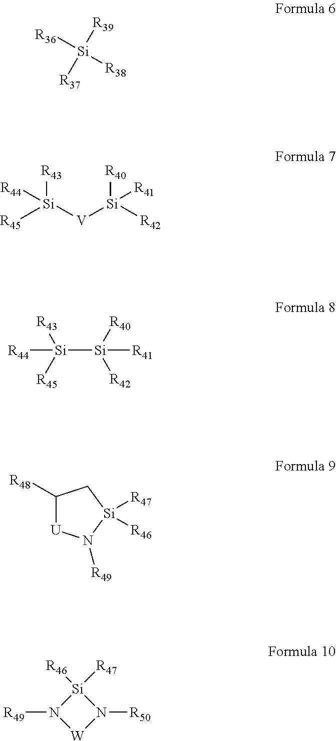
wherein R₃₆, R₃₇, R₃₈, R₃₉, R₄₀, R₄₁, R₄₂, R₄₃, R₄₄, R₄₅, R₄₆, R₄₇, R₇₉, and R₈₀ are independently selected from hydrogen, halogen, linear or branched (C₁-C₁₈) alkyl, linear or branched (C₁-C₁₈) alkoxy, vinyl, allyl, butenyl, phenyl, tolyl, cyclohexyl, cyclooctyl, or norbornyl, or N(R₅₁)(R₅₂); V is optionally bidentate and is O, N(R₅₃), C(R₇₃)(R₇₄), linear or branched (C₁-C₈) alkyl, or —C(R₇₃)(R₇₄)—C(R₇₅)(R₇₆)— wherein C₇₃, C₇₄, C₇₅ and C₇₆ are hydrogen or linear or branched (C₁-C₈)alkyl; R₄₉, R₅₀, R₅₁, R₅₂ and R₅₃ are hydrogen, a linear or branched (C₁-C₈) alkyl group, or —Si(R₅₄)(R₅₅)(R₅₆); R₅₄, R₅₅ and R₅₆ are independently selected from hydrogen, linear or branched (C₁-C₈alkyl), linear or branched (C₁-C₈)alkoxy, or —N(R₅₇)(R₅₈); R₅₇ and R₅₈ are independently hydrogen or (C₁-C₈)alkyl; R₄₈ is hydrogen or linear or branched (C₁-C₈) hydrocarbon; W is optionally bidentate and forms a ring with the adjacent nitrogen, silicon, and/or carbon atoms and is a linear or branched (C₁-C₈) alkyl, C(R₅₉)(R₆₀), —C(R₅₉)(R₆₀)—C(R₆₁)(R₆₂)—, —C(R₅₉)(R₆₀)—C(R₆₁)(R₆₂)—C(R₆₃)(R₆₄)— or —Si(R₆₅)(R₆₆)—N(R₆₇)—Si(R₆₈)(R₆₉)—; R₅₉, R₆₀, R₆₁, R₆₂, R₆₃, R₆₄ are independently hydrogen, linear or branched (C₁-C₈)alkyl; R₆₅, R₆₆, R₆₈ and R₆₉ are hydrogen, halide, (C₁-C₈) alkyl, O(R₇₀) or N(R₇₁)(R₇₂); R₇₀ is linear or branched (C₁-C₈)alkyl; U is C(R₇₇)(R₇₈) or Si(R₇₉)Si(R₈₀); R₆₇, R₇₁, R₇₂, R₇₇, and R₇₈ are independently hydrogen or linear or branched (C₁-C₈)alkyl; and wherein the precursor compound contains at least one silicon-nitrogen or silicon-halide bond, and at least one silicon-carbon bond.

36. The method according to claim 35, wherein all but a final exposure of the substrate to the two or more silicon-containing compounds covers only a fraction of the available substrate surface or is followed by an exposure to low-water content hydrogen peroxide.

37. The method according to claim 35, further comprising prior to or after step (j2):
(j1) performing at least one ex-situ annealing, cleaning, etching, polishing, oxidation, reduction, photolysis, UV/ozone exposure, or plasma treatment of the patterned substrate.

38. The method according to claim 35, further comprising prior to or after step (k2):
(k1) heating or cooling the reaction zone to about 0° C. to about 800° C. and performing at least one in-situ annealing, cleaning, etching, polishing, oxidation, reduction, photolysis, UV/ozone exposure, chemical modification, passivation or plasma treatment of the patterned substrate.

39. The method according to claim 35, wherein at least one passivation step (j2) or (k2) meets the following criteria:
(i) when the substrate comprises silicon dioxide, silicon oxycarbide, silicon oxynitride, silicon carboxynitride, or germanium dioxide, exposing the patterned substrate to a compound having Formula 11 or Formula 12 to selectively passivate regions of the substrate; or
(ii) when the substrate comprises silicon nitride, titanium nitride, tantalum nitride, or germanium nitride, exposing the patterned substrate to a compound containing an aldehyde functional group to selectively passivate regions of the substrate; or
(iii) when the substrate comprises copper, cobalt, molybdenum, ruthenium, and/or tungsten, exposing the patterned substrate to an N-heterocyclic carbene or a chemical compound containing sulfur or phosphorus to selectively passivate regions of the substrate; or
(iv) when the substrate comprises silicon, germanium, copper, cobalt, molybdenum, ruthenium, or tungsten, exposing the patterned substrate to a chemical compound of Formula 13 to selectively passivate regions of the substrate; or
(v) when the substrate comprises aluminum oxide, exposing the patterned substrate to a chemical compound of Formula 11, Formula 12, Formula 14, or Formula 15 to selectively passivate regions of the substrate: 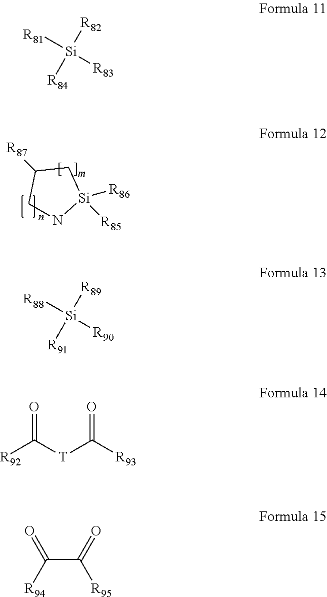
wherein R₈₁, R₈₂, R₈₃, and R₈₄ are independently hydrogen, halogen, linear or branched (C₁-C₈)alkyl, linear or branched (C₁-C₈)alkoxy, or N(R₉₆)N(₉₇), wherein R₉₆ and R₉₇ are independently hydrogen or (C₁-C₈)alkyl, and at least one of R₈₁, R₈₂, R₈₃, and R₈₄ is a linear or branched (C₁-C₈)alkyl and at least one is N(R₉₆)R₉₇; R₈₅ and R₈₆ are hydrogen, halogen, linear or branched (C₁-C₈)alkyl, linear or branched (C₁-C₈)alkoxy, or N(R₉₆)(R₉₇); R₈₈, R₈₉, R₉₀ and R₉₁ are independently hydrogen or (C₁-C₁₈)alkyl, and at least one of R₈₈, R₈₉, R₉₀, or R₉₁ is hydrogen and at least one is (C₁-C₁₈)alkyl; T is linear or branched (C₁-C₄)alkyl; and R₉₂, R₉₃, R₉₄ and R₉₅ are hydrogen or (C₁-C₄)alkyl; wherein R₅₇ is hydrogen or linear or branched (C₁-C₄)alkyl; and wherein n and m are 1, 2, or 3.

40. The method according to claim 35, wherein the silicon-containing compound having Formula 1, Formula 2, Formula 3, Formula 4, or Formula 5 is tris(dimethylamino)silane, tetrakis(dimethylamino)silane, 1,4,6,9-tetramethyl-1,4,6,9-tetraaza-5-silaspiro[4.4]nonane, 2,2-dimethoxy-1,3-dimethyl-1,3-diaza-2-silacyclopentane, trisilylamine, bis(diethylamino)silane, bis(isopropylamino)silane, 1,2,4,6,8,9-hexamethyl-1,4,6,9-tetraaza-5-silaspiro[4.4]nonane, 1,4,6,9-tetraaza-5-silaspiro[4.4]nonane, penta(dimethylamino)disilane, bis(t-butylamino)silane, bis(dimethylamino)dimethoxysilane, bis(dimethylamino)silane, 1,3,5-tris(1-methylethyl)-1,3,5-triaza-2,4,6-trisilacyclohexane, hexa(ethylamino)disilane, di-sec-butylaminosilane, hexa(dimethylamino)disiloxane, bis(bis(dimethylamino)silylamino)(dimethylamino)silane, hexa(dimethylamino)silazane, tetrachlorosilane, tris(dimethylamino)chlorosilane, 1,2-bis(dimethylamino)disilane, hexakis(ethylamino)disilane, tris(ethylaminosilane), tri(isopropylamino)silane, tris(n-propylamino)silane, tris(t-butyl)aminosilane, tris(n-butylaminosilane), tris(sec-butylaminosilane), tris(diethylamino)silane, tris(diisopropyl)aminosilane, tris(di-n-propyl)aminosilane, tris(di-t-butylamino)silane, tris(di-n-butylamino)silane or tris(di-sec-butylamino)silane.

41. The method according to claim 40, wherein the silicon-containing compound having Formula 1, Formula 2, Formula 3, Formula 4, or Formula 5 is tris(dimethylamino)silane, tris(dimethylamino)chlorosilane, tris(diethylamino)silane, tris(ethylamino)silane, or tris(isopropylamino)silane.

42. The method according to claim 35, wherein the silicon-containing compound having Formula 6, Formula 7, Formula 8, Formula 9, or Formula 10 is tris(dimethylamino)methylsilane, bis(diethylamino)methylsilane, di(isopropylamino)methylsilane, dimethylamino-(dimethoxy)methylsilane, tris(dimethylamino)(t-butyl)silane, tris(dimethylamino)phenylsilane, dimethylamino(dimethyl)cyclohexylsilane, 2-(dimethylaminosilyl)bicyclo[2.2.1]heptane, tris(dimethylamino)decylsilane, n-methyl-aza-2,2,4-trimethylsilacyclopentane, n-trimethylsilyl-aza-4-methylsilacyclopentane, n-(n-butyl)-aza-silacyclopentane, n-ethyl-aza-4-methyl-2,2-dimethoxysilacyclopentane, 1,2,2,3-tetramethyl-1,3-diaza-2-silacyclopentane, N-methyl-aza-4-methyl-2-methoxy-2-(n-butyl)silacyclopentane, bis(dimethylaminomethylsilyl)methane, bis(tris(dimethylamino)silyl)methane, bis(bis(dimethylamino)methylsilyl)methane, 1,1-bis(tris(dimethylamino)silyl)ethane, bis(bis(dimethylamino)methylsilylamino)-(dimethylamino)methylsilane, (bis(dimethylamino)methylsilylamino)-bis(dimethylamino)methylsilane, bis(bis(dimethylamino)silyl)methane, (bis(ethylamino)methylsilyl)bis(ethylamino)-methylsilane, and 1,3,5-tris(1-methylethyl)-1,3,5-triaza-2,4,6-trimethyl-2,4,6-trisilacyclohexane, 2,2,5,5-tetramethyl-1-aza-2,5-disilacyclopentane, dimethylamino(trimethoxy)silane, or n-trimethylsilyl-aza-silacyclopentane.

43. The method according to claim 42, wherein the silicon-containing compound having Formula 6, Formula 7, Formula 8, Formula 9, or Formula 10 is tris(dimethylamino)methylsilane, bis(tris(dimethylamino)silyl)methane, n-methyl-aza-2,2,4-trimethylsilacyclopentane or bis(dimethylaminomethylsilyl)methane.

44. The method according to claim 35, wherein a temperature of the reaction zone in step (k) is below about 100° C.

45. The method according to claim 44, wherein the temperature of the reaction zone in step (k) is below about 50° C.

46. The method according to claim 35, wherein the hydrogen peroxide comprises less than about 30 weight percent water.

47. The method according to claim 46, wherein the hydrogen peroxide comprises less than about 20 weight percent water.

48. The method according to claim 47, wherein the hydrogen peroxide comprises less than about 10 weight percent water.

49. The method according to claim 35, wherein the deposition rate of the silicon- or silicon- and carbon-containing layer is greater than about 0.3 angstroms per cycle and a cycle time is less than about 120 seconds.

50. The method according to claim 49, wherein the deposition rate of the silicon- or silicon- and carbon-containing layer is greater than about 0.5 angstroms per cycle and a cycle time less than about 60 seconds.

51. The method according to claim 35, wherein the patterned substrate has growth and non-growth surfaces, and wherein a selectivity ratio between the growth and the non-growth surfaces is at least about 2:1.

52. The method according to claim 51 wherein the selectivity ratio between the growth and the non-growth surfaces is at least about 5:1.

53. The method according to claim 52, wherein the selectivity ratio between the growth and the non-growth surfaces is at least about 10:1.

54. The method according to claim 35, wherein after step (1) or (n), the method further comprises:
(d) heating or cooling the reaction zone to about 0° C. to about 800° C.; and
(e) performing at least one in-situ passivation, annealing, cleaning, etching, polishing, oxidation, reduction, photolysis, UV/ozone exposure, or plasma treatment of the substrate.

55. The method according to claim 54, further comprising after step (e);
(o) repeating steps (j) or (j2) through (e) until a desired layer thickness is reached.

56. The method according to claim 35, wherein the substrate comprises a semiconductor device, an active pharmaceutical ingredient, a drug product, a polymer, or a polymer film.
